(19) United States
(12) Patent Application Publication
(10) Pub. No.: US 2025/0089283 A1
(43) Pub. Date: Mar. 13, 2025

(54) SEMICONDUCTOR DEVICE MANUFACTURING METHOD AND SEMICONDUCTOR DEVICE

(71) Applicant: KABUSHIKI KAISHA TOSHIBA, Tokyo (JP)

(72) Inventor: Tatsuo SHIMIZU, Shinagawa Tokyo (JP)

(73) Assignee: KABUSHIKI KAISHA TOSHIBA, Tokyo (JP)

(21) Appl. No.: 18/594,454

(22) Filed: Mar. 4, 2024

(30) Foreign Application Priority Data
Sep. 12, 2023 (JP) 2023-147489

(51) Int. Cl. H01L 29/66; H01L 21/04; H01L 29/06; H01L 29/16; H01L 29/78

(52) U.S. Cl. CPC H10D 12/031; H01L 21/0465; H10D 30/668; H10D 62/102; H10D 62/8325

(57) ABSTRACT

A semiconductor device manufacturing method of embodiments includes: forming a mask material having openings on a surface of a silicon carbide layer; performing first processing for implanting at least one substance selected from a group consisting of hydrogen (H), helium (He), and electrons into a first region of the silicon carbide layer by using the mask material as a mask; performing a first ion implantation for implanting p-type impurities into a second region shallower than the first region by using the mask material as a mask before the first processing or after the first processing; removing the mask material after the first processing and the first ion implantation; and performing a first heat treatment at a temperature equal to or more than 1600° C. after removing the mask material.

### CROSS-REFERENCE TO RELATED APPLICATION

This application is based upon and claims the benefit of priority from Japanese Patent Application No. 2023-147489, filed on Sep. 12, 2023, the entire contents of which are incorporated herein by reference.

### FIELD

Embodiments described herein relate generally to a semiconductor device manufacturing method and a semiconductor device.

### BACKGROUND

Silicon carbide (SiC) is one of the materials for next-generation semiconductor devices. Silicon carbide has excellent physical properties, such as a bandgap of about 3 times, a breakdown field strength of about 10 times, and a thermal conductivity of about 3 times that of silicon (Si). By using these physical properties, it is possible to realize a semiconductor device that can operate at high temperature with low loss.

As a structure to achieve both high breakdown voltage and low on-resistance in vertical metal oxide semiconductor field effect transistors (MOSFETs), there is a superjunction structure (hereinafter, also referred to as “SJ structure”). In the SJ structure, a p-type region and an n-type region are arranged alternately in the horizontal direction. A depletion layer extending in the horizontal direction in the p-type region and the n-type region reduces the field strength in the semiconductor, thereby realizing a high breakdown voltage of the MOSFET. At the same time, by increasing the concentration of the impurity region, it is possible to realize the low on-resistance of the MOSFET.

In the SJ-structure MOSFET, it is required to form a deep p-type region in the silicon carbide layer. Therefore, there is a need for a method that can easily form a deep p-type region.

### BRIEF DESCRIPTION OF THE DRAWINGS

FIG. 1 is a schematic cross-sectional view of a semiconductor device according to a first embodiment;

FIG. 2 is a schematic plan view of the semiconductor device according to the first embodiment;

FIG. 3 is a schematic cross-sectional view showing an example of a semiconductor device manufacturing method according to the first embodiment;

FIG. 4 is a schematic cross-sectional view showing an example of the semiconductor device manufacturing method according to the first embodiment;

FIG. 5 is a schematic cross-sectional view showing an example of the semiconductor device manufacturing method according to the first embodiment;

FIG. 6 is a schematic cross-sectional view showing an example of the semiconductor device manufacturing method according to the first embodiment;

FIG. 7 is a schematic cross-sectional view showing an example of the semiconductor device manufacturing method according to the first embodiment;

FIG. 8 is a schematic cross-sectional view showing an example of the semiconductor device manufacturing method according to the first embodiment;

FIG. 9 is a schematic cross-sectional view showing an example of the semiconductor device manufacturing method according to the first embodiment;

FIG. 10 is a schematic cross-sectional view showing an example of the semiconductor device manufacturing method according to the first embodiment;

FIG. 11 is a schematic cross-sectional view showing an example of the semiconductor device manufacturing method according to the first embodiment;

FIG. 12 is a schematic cross-sectional view of a semiconductor device according to a second embodiment;

FIG. 13 is a schematic plan view of the semiconductor device according to the second embodiment;

FIG. 14 is a schematic cross-sectional view showing an example of a semiconductor device manufacturing method according to the second embodiment;

FIG. 15 is a schematic cross-sectional view showing an example of the semiconductor device manufacturing method according to the second embodiment;

FIG. 16 is a schematic cross-sectional view showing an example of the semiconductor device manufacturing method according to the second embodiment;

FIG. 17 is a schematic cross-sectional view showing an example of the semiconductor device manufacturing method according to the second embodiment;

FIG. 18 is a schematic cross-sectional view showing an example of the semiconductor device manufacturing method according to the second embodiment;

FIG. 19 is a schematic cross-sectional view showing an example of the semiconductor device manufacturing method according to the second embodiment;

FIG. 20 is a schematic cross-sectional view showing an example of the semiconductor device manufacturing method according to the second embodiment;

FIG. 21 is a schematic cross-sectional view showing an example of the semiconductor device manufacturing method according to the second embodiment;

FIG. 22 is a schematic cross-sectional view showing an example of the semiconductor device manufacturing method according to the second embodiment;

FIG. 23 is a schematic cross-sectional view showing an example of the semiconductor device manufacturing method according to the second embodiment;

FIG. 24 is a schematic cross-sectional view showing an example of the semiconductor device manufacturing method according to the second embodiment;

FIG. 25 is a schematic cross-sectional view showing an example of the semiconductor device manufacturing method according to the second embodiment;

FIG. 26 is a schematic cross-sectional view of a semiconductor device manufactured by a semiconductor device manufacturing method according to a third embodiment;

FIG. 27 is a schematic cross-sectional view showing an example of the semiconductor device manufacturing method according to the third embodiment;

FIG. 28 is a schematic cross-sectional view showing an example of the semiconductor device manufacturing method according to the third embodiment;

FIG. 29 is a schematic cross-sectional view showing an example of the semiconductor device manufacturing method according to the third embodiment;

FIG. 30 is a schematic cross-sectional view showing an example of the semiconductor device manufacturing method according to the third embodiment;

FIG. 31 is a schematic cross-sectional view showing an example of the semiconductor device manufacturing method according to the third embodiment;

FIG. 32 is a schematic cross-sectional view showing an example of the semiconductor device manufacturing method according to the third embodiment;

FIG. 33 is a schematic cross-sectional view showing an example of the semiconductor device manufacturing method according to the third embodiment;

FIG. 34 is a schematic cross-sectional view showing an example of the semiconductor device manufacturing method according to the third embodiment; and

FIG. 35 is a schematic cross-sectional view showing an example of the semiconductor device manufacturing method according to the third embodiment.

### DETAILED DESCRIPTION

A semiconductor device manufacturing method of embodiments includes: forming a mask material having openings on a surface of a silicon carbide layer; performing first processing for implanting at least one substance selected from a group consisting of hydrogen (H), helium (He), and electrons into a first region of the silicon carbide layer by using the mask material as a mask; performing a first ion implantation for implanting p-type impurities into a second region shallower than the first region by using the mask material as a mask before the first processing or after the first processing; removing the mask material after the first processing and the first ion implantation; and performing a first heat treatment at a temperature equal to or more than 1600° C. after removing the mask material.

Hereinafter, embodiments will be described with reference to the diagrams. In addition, in the following description, the same or similar members and the like are denoted by the same reference numerals, and the description of the members and the like once described will be omitted as appropriate.

In addition, in the following description, when there are notations of n⁺, n, n⁻, p⁺, p, and p⁻, these indicate the relative high and low of the impurity concentration in each conductive type. That is, n⁺indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type. Unless otherwise specified, the impurity concentration in each region is represented by, for example, the value of the impurity concentration in the central portion of each region.

The impurity concentration can be measured by, for example, secondary ion mass spectrometry (SIMS). In addition, the relative high and low of the impurity concentration can be determined from, for example, the high and low of the carrier concentration obtained by scanning capacitance microscopy (SCM). In addition, the distance such as the width or depth of an impurity region can be calculated by, for example, SIMS. In addition, the distance such as the width or depth of an impurity region can be calculated from, for example, an SCM image.

### First Embodiment

A semiconductor device according to a first embodiment includes: a first electrode; a second electrode; a silicon carbide layer disposed between the first electrode and the second electrode, having a first face parallel to a first direction and a second direction crossing the first direction and a second face parallel to the first direction and the second direction and opposite to the first face, and including a p-type first silicon carbide region and an n-type second silicon carbide region arranged alternately in the first direction, a p-type third silicon carbide region disposed between the second silicon carbide region and the first face, and an n-type fourth silicon carbide region disposed between the third silicon carbide region and the first face; a gate electrode provided on a side of the first face of the silicon carbide layer, facing the third silicon carbide region, and extending in the second direction; and a gate insulating layer disposed between the gate electrode and the silicon carbide layer, wherein a Z_{1/2} level density in the first silicon carbide region measured by deep level transient spectroscopy (DLTS) is lower than a Z_{1/2} level density in the second silicon carbide region measured by DLTS.

A semiconductor device manufacturing method according to the first embodiment includes: forming a mask material having openings on a surface of a silicon carbide layer; performing first processing for implanting at least one substance selected from a group consisting of hydrogen (H), helium (He), and electrons into a first region of the silicon carbide layer by using the mask material as a mask; performing a first ion implantation for implanting p-type impurities into a second region shallower than the first region by using the mask material as a mask before the first processing or after the first processing; removing the mask material after the first processing and the first ion implantation; and performing a first heat treatment at a temperature equal to or more than 1600° C. after removing the mask material.

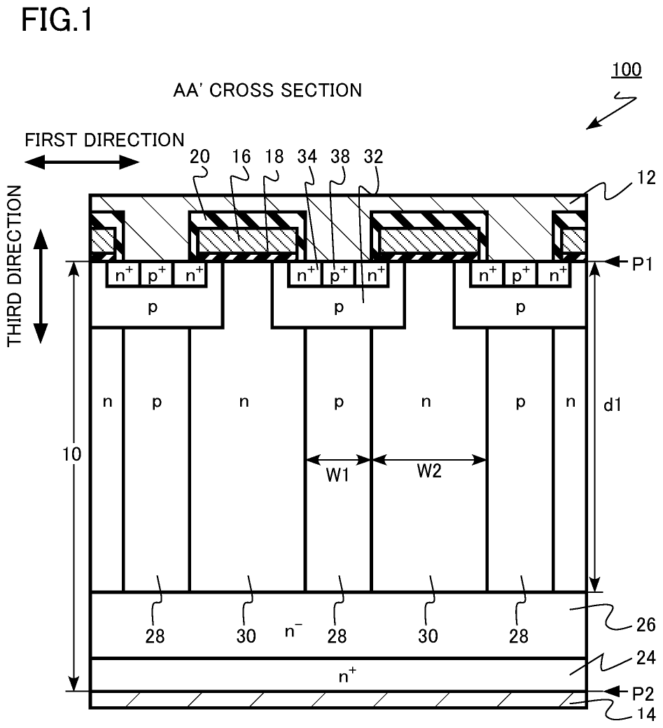

FIG. 1 is a schematic cross-sectional view of the semiconductor device according to the first embodiment. The semiconductor device according to the first embodiment is a planar gate type vertical MOSFET 100 using silicon carbide. The MOSFET 100 is an n-channel MOSFET having electrons as carriers. The MOSFET 100 has a superjunction structure (SJ structure).

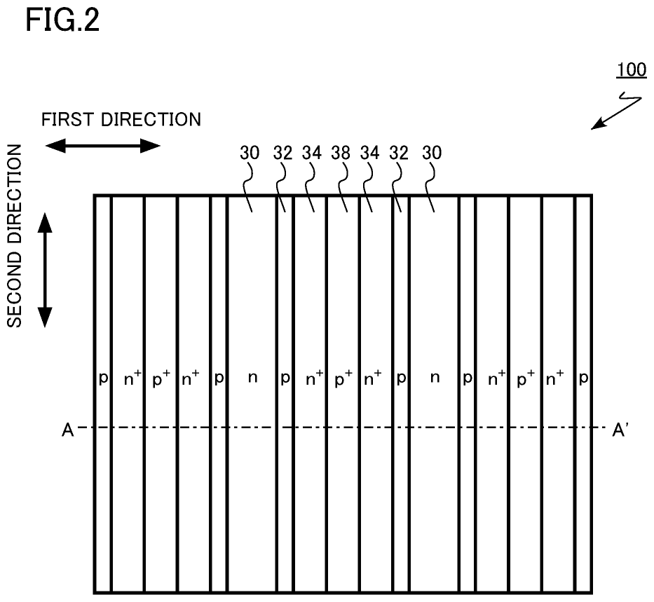

FIG. 2 is a schematic plan view of the semiconductor device according to the first embodiment. FIG. 2 is a plan view of a first face (P1 in FIG. 1) in FIG. 1. FIG. 1 is a cross-sectional view taken along the line AA′ of FIG. 2.

The MOSFET 100 includes a silicon carbide layer 10, a source electrode 12 (first electrode), a drain electrode 14 (second electrode), a gate electrode 16, a gate insulating layer 18, and an interlayer insulating layer 20. The silicon carbide layer 10 has an n⁺-type drain region 24, an n⁻-type drift region 26, a p-type p-pillar region 28 (first silicon carbide region), an n-type n-pillar region 30 (second silicon carbide region), a p-type body region 32 (third silicon carbide region), an n⁺-type source region 34 (fourth silicon carbide region), and a p⁺-type contact region 38.

The silicon carbide layer 10 is disposed between the source electrode 12 and the drain electrode 14. The silicon carbide layer 10 includes a first face (“P1” in FIG. 1) and a second face (“P2” in FIG. 1). Hereinafter, the first face P1 is also referred to as a surface, and the second face P2 is also referred to as a back surface. The second face P2 is opposite to the first face P1.

The first direction and the second direction are directions parallel to the first face P1. In addition, the second direction is a direction crossing the first direction. The second direction is, for example, a direction perpendicular to the first direction. In addition, the third direction is a direction perpendicular to the first face. The third direction is a direction perpendicular to the first direction and the second direction.

Hereinafter, “depth” means a depth with respect to the first face P1. In addition, “thickness” means a length in the third direction.

The silicon carbide layer 10 is a single crystal SiC. The silicon carbide layer 10 is, for example, 4H—SiC. The thickness of the silicon carbide layer 10 is, for example, equal to or more than 5 μm and equal to or less than 500 μm.

The first face P1 is, for example, a face inclined by an angle equal to or more than 0 degrees and equal to or less than 8 degrees with respect to the (0001) face. That is, the first face P1 is a face whose normal is inclined by an angle equal to or more than 0 degrees and equal to or less than 8 degrees with respect to the c axis in the direction. In other words, an off angle with respect to the (0001) face is equal to or more than 0 degrees and equal to or less than 8 degrees. In addition, the second face P2 is, for example, a face inclined by an angle equal to or more than 0 degrees and equal to or less than 8 degrees with respect to the (000-1) face. The (0001) face is referred to as a silicon face. The (000-1) face is referred to as a carbon face. The inclination direction of the first face P1 and the second face P2 is, for example, a [11-20] direction. The [11-20] direction is an a-axis direction. In FIG. 1, for example, the first direction shown in the diagram is the a-axis direction.

The gate electrode 16 is provided on the first face P1 side of the silicon carbide layer 10. The gate electrode 16 is provided between the source electrode 12 and the drain electrode 14. The gate electrode 16 extends in the second direction.

The gate electrode 16 is a conductive layer. The gate electrode 16 is, for example, polycrystalline silicon containing p-type impurities or n-type impurities.

The gate insulating layer 18 is disposed between the gate electrode 16 and the silicon carbide layer 10. The gate insulating layer 18 is provided between the source region 34, the body region 32, and the n-pillar region 30 and the gate electrode 16.

The gate insulating layer 18 is, for example, a silicon oxide film. As the gate insulating layer 18, for example, a high dielectric constant insulating film having a higher dielectric constant than a silicon oxide film can be applied. In addition, as the gate insulating layer 18, for example, a stacked film of a silicon oxide film and a high dielectric constant insulating film can also be applied.

The interlayer insulating layer 20 is provided on the gate electrode 16. The interlayer insulating layer 20 is, for example, a silicon oxide film. The interlayer insulating layer 20 electrically separates the gate electrode 16 and the source electrode 12 from each other.

The source electrode 12 is provided on the first face P1 side of the silicon carbide layer 10. The source electrode 12 is provided on the first face P1 of the silicon carbide layer 10. The source electrode 12 is in contact with the source region 34 and the contact region 38.

The source electrode 12 contains metal. The metal forming the source electrode 12 has, for example, a stacked structure of titanium (Ti) and aluminum (Al). The source electrode 12 may contain metal silicide or metal carbide in contact with the silicon carbide layer 10.

The drain electrode 14 is provided on the second face P2 side of the silicon carbide layer 10. The drain electrode 14 is provided on the second face P2 of the silicon carbide layer 10. The drain electrode 14 is in contact with the drain region 24.

The drain electrode 14 is, for example, a metal or a metal semiconductor compound. The drain electrode 14 contains, for example, a material selected from the group consisting of nickel silicide (NiSi), titanium (Ti), nickel (Ni), silver (Ag), and gold (Au).

The n⁺-type drain region 24 is provided on the second face P2 side of the silicon carbide layer 10. The drain region 24 is disposed between the second face P2 and the p-pillar region 28 and n-pillar region 30.

The drain region 24 contains, for example, nitrogen (N) as an n-type impurity. The n-type impurity concentration in the drain region 24 is higher than the n-type impurity concentration in the n-pillar region 30. The n-type impurity concentration in the drain region 24 is, for example, equal to or more than 1×10¹⁸ cm⁻³ and equal to or less than 1×10²¹ cm⁻³.

The n⁻-type drift region 26 is provided on the drain region 24. The drift region 26 is disposed between the second face P2 and the p-pillar region 28 and the n-pillar region 30. The n-type impurity concentration in the drift region 26 is, for example, equal to or less than the n-type impurity concentration in the n-pillar region 30. For example, the n-type impurity concentration in the drift region 26 is lower than the n-type impurity concentration in the n-pillar region 30.

The drift region 26 contains, for example, nitrogen (N) as an n-type impurity. The n-type impurity concentration in the drift region 26 is, for example, equal to or more than 4×10¹⁴ cm⁻³ and equal to or less than 1×10¹⁸ cm⁻³.

The p-type p-pillar region 28 and the n-type n-pillar region 30 are provided between the drain region 24 and the first face P1. The p-pillar region 28 and the n-pillar region 30 are provided between the drift region 26 and the first face P1.

The p-pillar region 28 and the n-pillar region 30 are arranged alternately in the first direction. The p-pillar region 28 and the n-pillar region 30 form a so-called superjunction structure (SJ structure).

In the MOSFET 100 having the SJ structure, a depletion layer extends in a horizontal direction (first direction) between the p-pillar region 28 and the n-pillar region 30 during off-operation. By extending the depletion layer in the horizontal direction, the field strength in the silicon carbide layer 10 is reduced and accordingly, a high breakdown voltage can be realized.

The p-pillar region 28 contains, for example, aluminum (Al) as a p-type impurity. The p-type impurity concentration in the p-pillar region 28 is, for example, equal to or more than 5×10¹⁵ cm⁻³ and equal to or less than 5×10¹⁷ cm⁻³.

The n-pillar region 30 contains, for example, nitrogen (N) as an n-type impurity. The n-type impurity concentration in the n-pillar region 30 is, for example, equal to or more than 5×10¹⁵ cm⁻³ and equal to or less than 5×10¹⁷ cm⁻³.

For example, assuming that the width of the p-pillar region 28 in the second direction is W1, the p-type impurity concentration in the p-pillar region 28 is N1, the width of the n-pillar region 30 in the second direction is W2, and the n-type impurity concentration in the n-pillar region 30 is N2, the following relationship is satisfied.

$$0.8 \leq ( W 1 \times N 1 ) / ( W 2 \times N 2 ) \leq 1.2$$

The aspect ratio (d1/W1) between the depth d1 of the p-pillar region 28 in the third direction and the width (W1 in FIG. 1) of the p-pillar region 28 in the second direction is, for example, equal to or more than 3. The depth d1 of the p-pillar region 28 in the third direction perpendicular to the first face is, for example, equal to or more than 5 μm and equal to or less than 10 μm.

The Z_{1/2} level density in the p-pillar region 28 measured by deep level transient spectroscopy (DLTS) is lower than the Z_{1/2} level density in the n-pillar region 30 measured by DLTS. The Z_{1/2} level density in the p-pillar region 28 is, for example, equal to or less than 50% of the Z_{1/2} level density in the n-pillar region 30.

The Z_{1/2} level density measured by DLTS corresponds to the density of carbon vacancies. Therefore, the density of carbon vacancies in the p-pillar region 28 is lower than the density of carbon vacancies in the n-pillar region 30.

The p-type body region 32 is disposed between the n-pillar region 30 and the first face P1. The p-type body region 32 is disposed between the p-pillar region 28 and the first face P1.

The body region 32 functions as a channel region of the MOSFET 100. For example, when the MOSFET 100 is turned on, a channel through which electrons flow is formed in a region of the body region 32 in contact with the gate insulating layer 18. The region of the body region 32 in contact with the gate insulating layer 18 becomes a channel forming region.

The body region 32 contains, for example, aluminum (Al) as a p-type impurity. The p-type impurity concentration in the body region 32 is, for example, equal to or more than 5×10¹⁶ cm⁻³ and equal to or less than 5×10¹⁷ cm⁻³.

The depth of the body region 32 is, for example, equal to or more than 0.2 μm and equal to or less than 1.0 μm.

The n⁺-type source region 34 is disposed between the body region 32 and the first face P1. The source region 34 is in contact with the source electrode 12. The source region 34 is in contact with the gate insulating layer 18.

The source region 34 contains, for example, phosphorus (P) as an n-type impurity. The n-type impurity concentration in the source region 34 is higher than the n-type impurity concentration in the drift region 26 and the n-pillar region 30. The n-type impurity concentration in the source region 34 is, for example, equal to or more than 1×10¹⁹ cm⁻³ and equal to or less than 1×10²¹ cm⁻³.

The depth of the source region 34 is shallower than the depth of the body region 32. The depth of the source region 34 is, for example, equal to or more than 0.1 μm and equal to or less than 0.3 μm.

The p⁺-type contact region 38 is disposed between the body region 32 and the first face P1. The contact region 38 is in contact with the source electrode 12.

As shown in FIG. 2, the contact region 38 has, for example, a stripe shape extending in the second direction.

The contact region 38 contains, for example, aluminum (Al) as a p-type impurity. The p-type impurity concentration in the contact region 38 is higher than the p-type impurity concentration in the body region 32, for example. The p-type impurity concentration in the contact region 38 is, for example, equal to or more than 1×10¹⁸ cm⁻³ and equal to or less than 1×10²¹ cm⁻³.

Next, an example of the semiconductor device manufacturing method according to the first embodiment will be described.

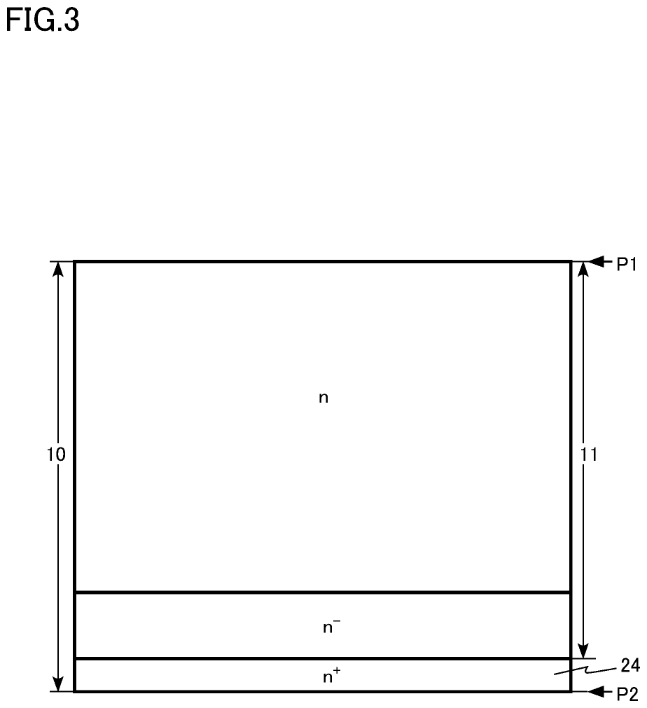

FIGS. 3 to 11 are schematic cross-sectional views showing an example of the semiconductor device manufacturing method according to the first embodiment. FIGS. 3 to 11 show cross sections corresponding to FIG. 1. Hereinafter, a case where the p-type impurity is aluminum (Al) will be described as an example.

First, the silicon carbide layer 10 having an n⁺-type drain region 24 and an n⁻-type and n-type epitaxial layer 11 is prepared (FIG. 3). The epitaxial layer 11 is a layer formed on the drain region 24 by epitaxial growth. A part of the epitaxial layer 11 finally becomes the drift region 26 and the n-pillar region 30.

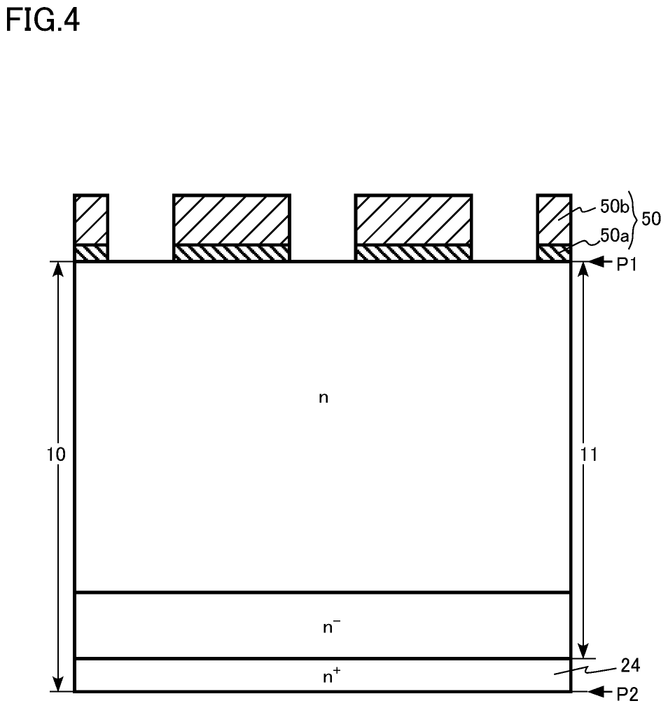

Then, a mask material 50 having openings is formed on the silicon carbide layer 10 (FIG. 4). The mask material 50 is, for example, a stacked film of a silicon oxide film 50a and a metal film 50b. The metal film 50b is, for example, tungsten.

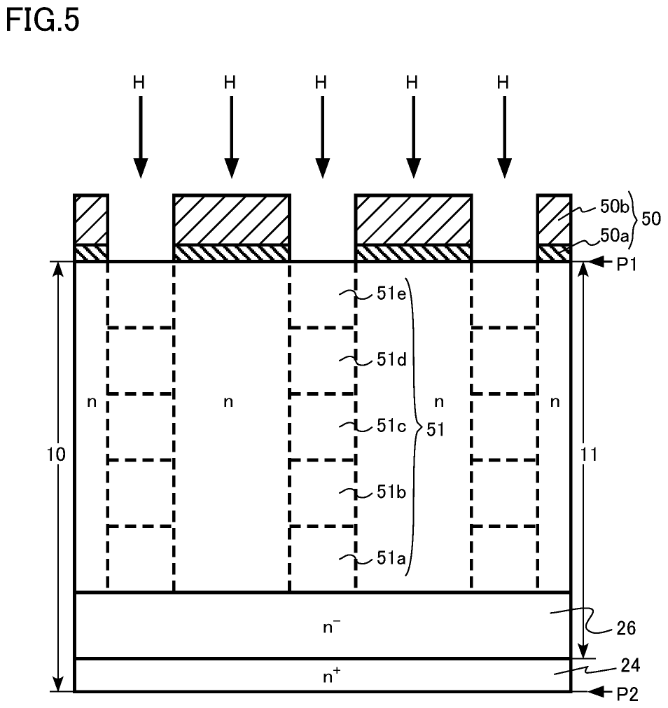

Then, hydrogen (H) is ion-implanted into the silicon carbide layer 10 by using the mask material 50 as a mask (FIG. 5). Hydrogen (H) is an example of a substance. Ion implantation of hydrogen (H) is an example of the first processing.

By the ion implantation of hydrogen (H), hydrogen (H) is implanted into a first region 51 of the silicon carbide layer 10. Ion implantation of hydrogen (H) includes multiple ion implantations. For example, ion implantation of hydrogen (H) includes five ion implantations.

Five ion implantations are performed at different accelerating voltages. Through the five ion implantations, hydrogen (H) is implanted into a first portion 51a, a second portion 51b, a third portion 51c, a fourth portion 51d, and a fifth portion 51e at different depths. For example, five ion implantations are performed so that the distribution of hydrogen (H) is continuous among the first portion 51a, the second portion 51b, the third portion 51c, the fourth portion 51d, and the fifth portion 51e.

Ion implantation of hydrogen (H) is performed so that the concentration of hydrogen (H) in the first region 51 is, for example, equal to or more than 1×10¹⁵ cm⁻³ and equal to or less than 1×10²¹ cm⁻³.

By the ion implantation of hydrogen (H), carbon vacancies are formed in the first region 51. Through the five ion implantations, carbon vacancies are formed in the first portion 51a, the second portion 51b, the third portion 51c, the fourth portion 51d, and the fifth portion 51e at different depths.

Ion implantation of hydrogen (H) is performed at a temperature equal to or more than 300° C., for example. Ion implantation of hydrogen (H) is performed, for example, while a holder on which the silicon carbide layer 10 is placed is held at a temperature equal to or more than 300° C. By performing the ion implantation of hydrogen (H) at a temperature equal to or more than 300° C., for example, a degradation in crystallinity of the silicon carbide layer 10 is suppressed.

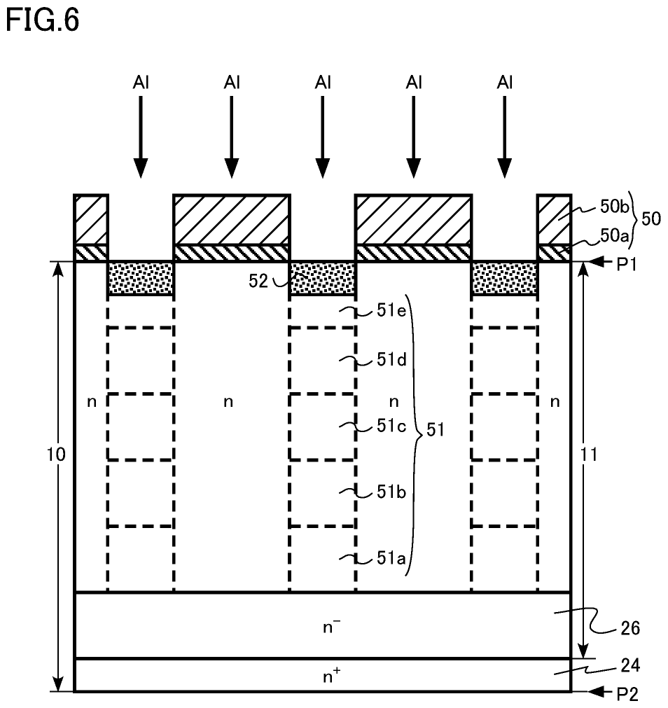

Then, aluminum (Al) is ion-implanted into the silicon carbide layer 10 by using the mask material 50 as a mask (FIG. 6). Ion implantation of aluminum (Al) is an example of the first ion implantation.

By the ion implantation of aluminum (Al), aluminum (Al) is implanted into a second region 52 of the silicon carbide layer 10. The second region 52 is shallower than the first region 51.

The second region 52 overlaps a part of the first region 51, for example. The second region 52 overlaps a part of the fifth portion 51e, for example. The depth of the first region 51 is, for example, equal to or more than three times the depth of the second region 52.

Ion implantation of aluminum (Al) is performed at a temperature equal to or more than 300° C., for example.

Ion implantation of aluminum (Al) can also be performed, for example, before ion implantation of hydrogen (H).

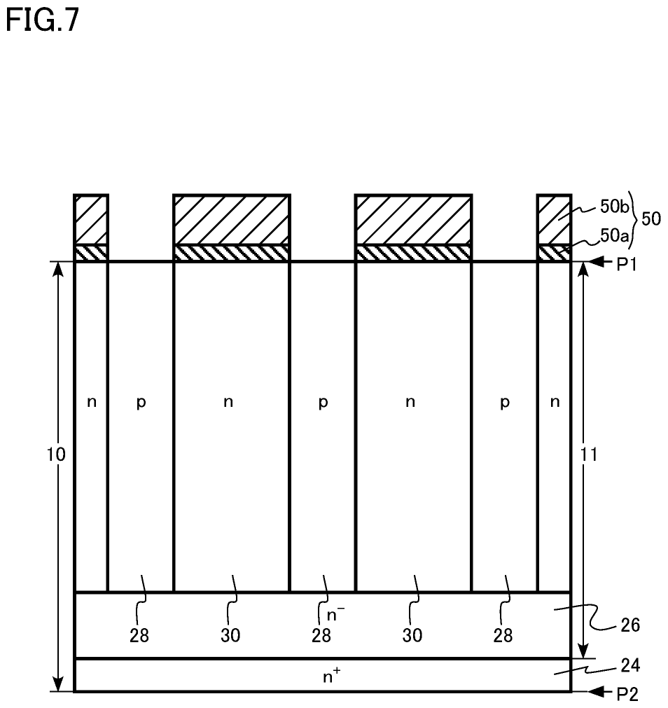

Then, a second heat treatment is performed at a temperature equal to or more than 300° C. (FIG. 7). The second heat treatment is performed in a non-oxidizing atmosphere. The second heat treatment is performed, for example, in an inert gas atmosphere. The second heat treatment is performed, for example, in an argon gas atmosphere.

Aluminum (Al) is diffused into the first region 51 by the second heat treatment, forming the p-pillar region 28. The region between the p-pillar region 28 and the p-pillar region 28 becomes the n-pillar region 30.

In addition, when ion implantation of aluminum (Al) is performed at a temperature equal to or more than 300° C., aluminum (Al) is diffused into the first region 51 even during the ion implantation of aluminum (Al). For example, if aluminum (Al) can be sufficiently diffused into the first region 51 during the ion implantation of aluminum (Al), the second heat treatment can be omitted.

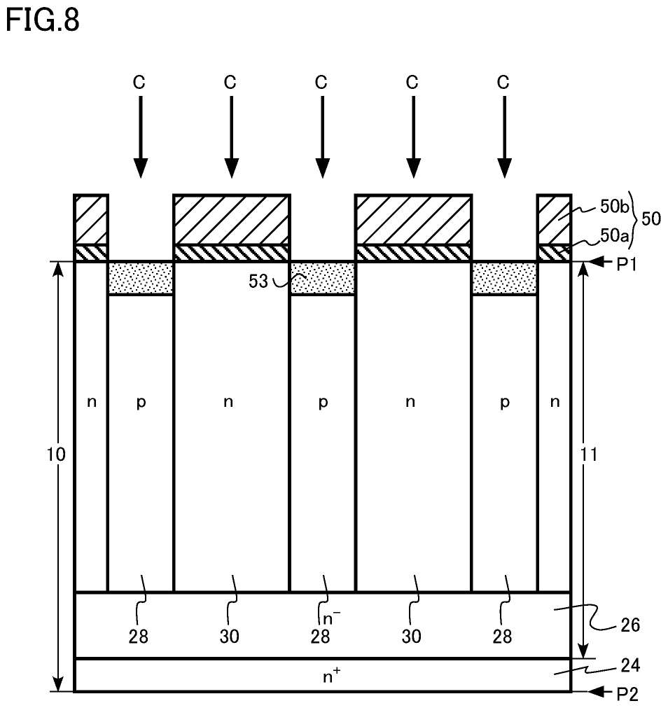

Then, a second ion implantation, which is ion implantation of carbon (C) into the silicon carbide layer 10, is performed by using the mask material 50 as a mask (FIG. 8). By the ion implantation of carbon (C), carbon (C) is implanted into a third region 53. The third region 53 is shallower than the first region 51.

Ion implantation of carbon (C) is performed at a temperature equal to or more than 300° C., for example.

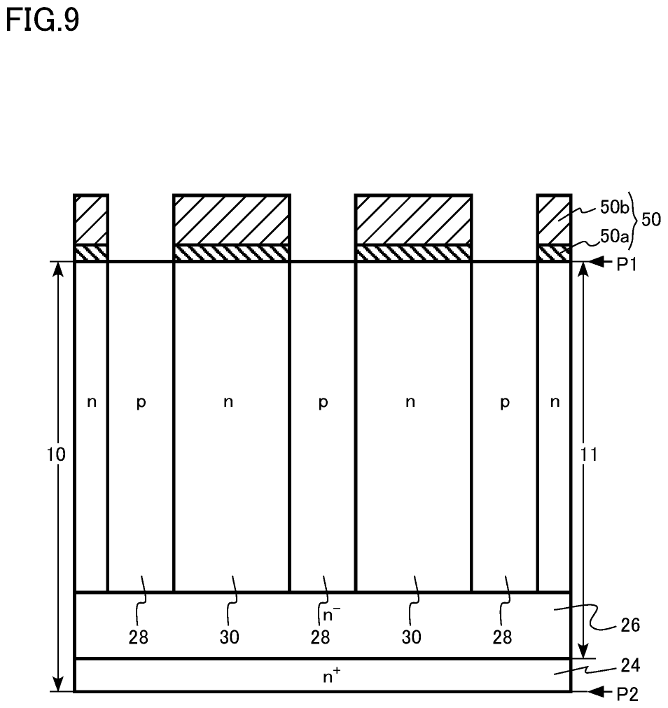

Then, a third heat treatment is performed at a temperature equal to or more than 300° C. (FIG. 9). The third heat treatment is performed in a non-oxidizing atmosphere. The third heat treatment is performed, for example, in an inert gas atmosphere. The third heat treatment is performed, for example, in an argon gas atmosphere.

By the third heat treatment, carbon (C) is diffused into the p-pillar region 28.

In addition, when ion implantation of carbon (C) is performed at a temperature equal to or more than 300° C., carbon (C) is diffused into the p-pillar region 28 during the ion implantation of carbon (C). For example, if carbon (C) can be sufficiently diffused into the p-pillar region 28 during the ion implantation of carbon (C), the third heat treatment can be omitted.

Then, the mask material 50 is removed. The mask material 50 is removed by using, for example, a wet etching method.

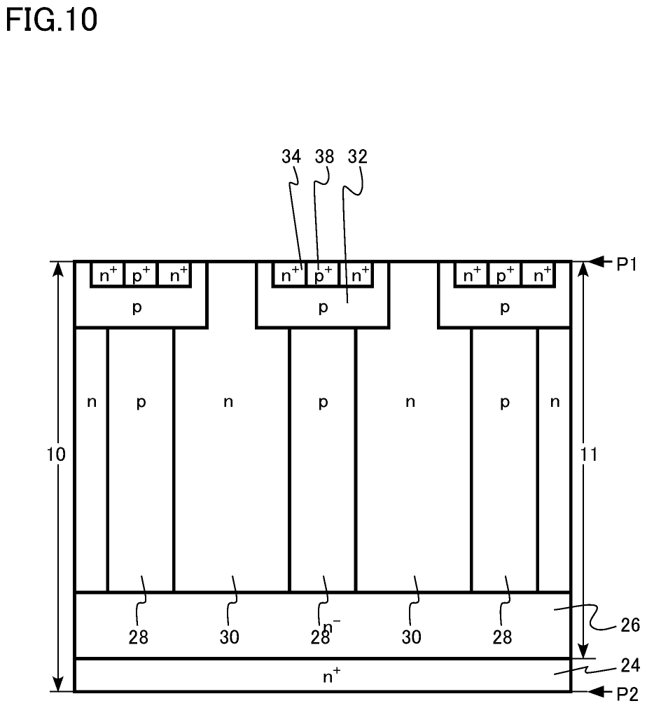

Then, the p-type body region 32, the n⁺-type source region 34, and the p⁺-type contact region 38 are formed in the epitaxial layer 11 by using known photolithography and ion implantation methods (FIG. 10).

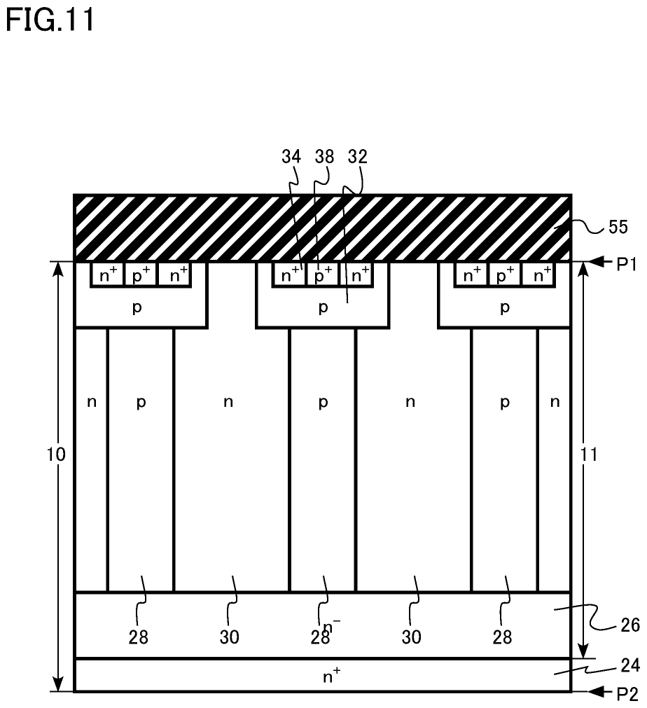

Then, a carbon film 55 is formed on the surface of silicon carbide layer 10 (FIG. 11).

Then, a first heat treatment is performed. The first heat treatment is performed at a temperature equal to or more than 1600° C. and equal to or less than 2000° C., for example. The first heat treatment is performed in a non-oxidizing atmosphere. The first heat treatment is performed, for example, in an inert gas atmosphere. The first heat treatment is performed, for example, in an argon gas atmosphere.

By the first heat treatment, ion-implanted aluminum (Al) is activated. In addition, through the first heat treatment, ion-implanted carbon (C) fills the carbon vacancies formed by ion implantation of hydrogen (H).

Then, using a known process technique, the gate insulating layer 18, the gate electrode 16, the interlayer insulating layer 20, the source electrode 12, and the drain electrode 14 are formed. By the manufacturing method described above, the MOSFET 100 shown in FIG. 1 is manufactured.

Next, the function and effect of the semiconductor device according to the first embodiment will be explained.

The MOSFET 100 has an SJ structure formed by the p-pillar region 28 and the n-pillar region 30. In the SJ structure, a depletion layer extending in the horizontal direction within the p-pillar region 28 and the n-pillar region 30 reduces the field strength in the semiconductor, thereby realizing a high breakdown voltage of the MOSFET 100. In addition, it is possible to increase the n-type impurity concentration in the n-pillar region 30 by having the SJ structure. Therefore, the on-resistance of the MOSFET 100 is reduced.

In the MOSFET 100, the Z_{1/2} level density in the p-pillar region 28 measured by deep level transient spectroscopy (DLTS) is lower than the Z_{1/2} level density in the n-pillar region 30 measured by DLTS. The Z_{1/2} level density measured by DLTS corresponds to the density of carbon vacancies. The density of carbon vacancies in the p-pillar region 28 is lower than the density of carbon vacancies in the n-pillar region 30.

As described above, in the SJ structure, a depletion layer extending in the horizontal direction within the p-pillar region 28 and the n-pillar region 30 reduces the field strength in the semiconductor, thereby realizing a high breakdown voltage of the MOSFET 100. The presence of carbon vacancies shortens the lifetime of carriers in silicon carbide. For example, the presence of carbon vacancies shortens the lifetime of holes in the p-pillar region 28 and the lifetime of electrons in the n-pillar region 30. In particular, the presence of carbon vacancies shortens the lifetime of holes compared with the lifetime of electrons.

Since the lifetime of holes is shorter than the lifetime of electrons, if the density of carbon vacancies in the p-pillar region 28 and the density of carbon vacancies in the n-pillar region 30 are the same, the balance between temporal changes in the depletion layer width of the p-pillar region 28 and the depletion layer width of the n-pillar region 30 is lost. Therefore, there is a possibility that the breakdown voltage of the MOSFET will decrease.

In the MOSFET 100, since the density of carbon vacancies in the p-pillar region 28 is lower than the density of carbon vacancies in the n-pillar region 30, the balance between temporal changes in the depletion layer width of the p-pillar region 28 and the depletion layer width of the n-pillar region 30 is maintained. Therefore, a high breakdown voltage of the MOSFET 100 can be realized.

In the SJ-structure MOSFET, it is required to form a deep p-type region in the silicon carbide layer. For example, it is required to form a deep p-type region of 5 μm or more. With normal ion implantation methods, it is difficult to implant p-type impurities, such as aluminum (Al) or boron (B), into a deep region of 5 μm or more.

For this reason, for example, there is a method in which when forming an SJ structure, epitaxial growth of a silicon carbide film, ion implantation of p-type impurities, and activation annealing of p-type impurities are repeated to form a deep p-type region in the silicon carbide layer. This method has a problem in that the manufacturing cost increases because the number of steps increases. In addition, this method requires alignment for ion implantation of p-type impurities. Therefore, there is a problem that this method is not suitable for scaling-down of MOSFETs.

For example, there is a method in which when forming an SJ structure, channeling ion implantation is performed to implant ions along a specific crystal axis when ion-implanting p-type impurities, thereby forming a deep p-type region in the silicon carbide layer. In this method, it is necessary to match the crystal orientation of the surface of the silicon carbide layer with the ion implantation direction with high precision. Therefore, there is a problem that variations in the depth of the p-type region increase due to variations in the crystal orientation of the surface of the silicon carbide layer.

In the semiconductor device manufacturing method according to the first embodiment, ion implantation of hydrogen (H) is performed before ion implantation of p-type impurities, forming the deep first region 51 with a high carbon vacancy density. Hydrogen (H) has a smaller ion radius than aluminum (Al) or boron (B). Therefore, it is easy to perform ion implantation of hydrogen (H) up to a deep region of 5 μm or more, for example. In the first region 51, the density of carbon vacancies in silicon carbide increases due to damage caused by ion implantation of hydrogen (H).

For example, after forming the deep first region 51 with a high carbon vacancy density, p-type impurities are ion-implanted. Thereafter, for example, p-type impurities are diffused by the second heat treatment. The presence of carbon vacancies in silicon carbide promotes the diffusion of p-type impurities. Therefore, for example, p-type impurities are diffused over the entire first region 51, so that it is possible to form a deep p-type region in the silicon carbide layer. Therefore, it is possible to form the deep p-pillar region 28 in the silicon carbide layer 10.

p-type impurities are diffused along the first region 51 with a high carbon vacancy density. Therefore, the diffusion of p-type impurities in the horizontal direction is suppressed. As a result, it is possible to form a p-type region with a large depth and a small width, in other words, a p-type region with a large aspect ratio.

According to the semiconductor device manufacturing method according to the first embodiment, it is possible to form a deep p-type region in a silicon carbide layer by using a simple manufacturing method with a small number of steps.

In addition, in the semiconductor device manufacturing method according to the first embodiment, ion implantation of hydrogen (H) and multiple ion implantations of p-type impurities are performed using the same mask material. Therefore, since there is no need to adjust the ion implantation, scaling-down of the MOSFET can be realized.

In addition, since the semiconductor device manufacturing method according to the first embodiment does not rely on channeling ion implantation, it is possible to form a p-type region with the same depth regardless of the crystal orientation of the surface of the silicon carbide layer 10. Therefore, according to the semiconductor device manufacturing method according to the first embodiment, it is possible to suppress variations in the depth of the p-type region. Since the substrate has an off angle, when ion implantation is performed from directly above the substrate, ions are implanted under conditions in which channeling does not occur. Therefore, there is almost no variation in the depth of ion implantation.

From the viewpoint of increasing the uniformity of carbon vacancy density from the deep portion to the shallow portion of the first region 51, it is preferable that the ion implantation of hydrogen (H) is performed by multiple ion implantations with different accelerating voltages.

From the viewpoint of promoting the diffusion of p-type impurities by increasing the carbon vacancy density, ion implantation of hydrogen (H) is preferably performed so that the concentration of hydrogen (H) in the first region 51 is equal to or more than 1×10¹⁵ cm⁻³, more preferably performed so that the concentration of hydrogen (H) in the first region 51 is equal to or more than 1×10¹⁶ cm⁻³, and even more preferably performed so that the concentration of hydrogen (H) in the first region 51 is equal to or more than 1×10¹⁷ cm⁻³.

From the viewpoint of suppressing a decrease in crystallinity of the silicon carbide layer 10, ion implantation of hydrogen (H) is preferably performed so that the concentration of hydrogen (H) in the first region 51 is equal to or less than 1×10²¹ cm⁻³, more preferably performed so that the concentration of hydrogen (H) in the first region 51 is equal to or less than 1×10²⁰ cm⁻³, and even more preferably performed so that the concentration of hydrogen (H) in the first region 51 is equal to or less than 1×10¹⁹ cm⁻³.

From the viewpoint of suppressing a decrease in crystallinity of the silicon carbide layer 10, ion implantation of hydrogen (H) is preferably performed at a temperature equal to or more than 300° C., more preferably performed at a temperature equal to or more than 500° C., and even more preferably performed at a temperature equal to or more than 900° C.

From the viewpoint of diffusing aluminum (Al) into the first region 51 during the first ion implantation that is ion implantation of aluminum (Al), the first ion implantation is preferably performed at a temperature equal to or more than 300° C., more preferably performed at a temperature equal to or more than 500° C., and even more preferably performed at a temperature equal to or more than 900° C.

From the viewpoint of promoting the diffusion of aluminum (Al) into the first region 51, the temperature of the second heat treatment performed after the first ion implantation is preferably equal to or more than 300° C., more preferably equal to or more than 500° C., and even more preferably equal to or more than 900° C.

From the viewpoint of eliminating carbon vacancies generated in the first region 51 by ion implantation of hydrogen (H), it is preferable to perform the second ion implantation, which is ion implantation of carbon (C) into the silicon carbide layer 10, after aluminum (Al) is diffused.

By performing the second ion implantation, the density of carbon vacancies in the p-pillar region 28 can be made lower than the density of carbon vacancies in the n-pillar region 30.

From the viewpoint of promoting the diffusion of carbon (C) into the p-pillar region 28, the second ion implantation is preferably performed at a temperature equal to or more than 300° C., more preferably performed at a temperature equal to or more than 500° C., and even more preferably performed at a temperature equal to or more than 900° C. In a series of ion implantations, since the mask material 50 is a stacked film of the silicon oxide film 50a and the metal film 50b, ion implantation in a high temperature range, which is difficult to perform with a resist, is realized. Since a hard mask such as the silicon oxide film 50a is used, the upper limit is about 1200° C.

From the viewpoint of promoting the diffusion of carbon (C) into the p-pillar region 28, the temperature of the third heat treatment performed after ion implantation of carbon (C) is preferably equal to or more than 300° C., more preferably equal to or more than 500° C., and even more preferably equal to or more than 900° C.

### First Modification Example

A semiconductor device manufacturing method according to a first modification example of the first embodiment is different from the semiconductor device manufacturing method according to the first embodiment in that the substance is helium (He) and the first processing is ion implantation of helium (He) into the first region.

Helium (He) has a smaller ion radius than aluminum (Al) or boron (B), similarly to hydrogen (H). Therefore, it is easy to perform ion implantation of helium (He) up to a deep region of 5 μm or more, for example.

According to the semiconductor device manufacturing method according to the first modification example of the first embodiment, the same function and effect as in the semiconductor device manufacturing method according to the first embodiment can be achieved.

### Second Modification Example

A semiconductor device manufacturing method according to a second modification example of the first embodiment is different from the semiconductor device manufacturing method according to the first embodiment in that the substance is electrons and the first processing is injection of electrons into the first region by electron beam irradiation.

An electron has a smaller diameter than aluminum (Al) or boron (B). Therefore, electrons can be easily injected up to a deep region of, for example, 5 μm or more by electron beam irradiation.

According to the semiconductor device manufacturing method according to the second modification example of the first embodiment, the same function and effect as in the semiconductor device manufacturing method according to the first embodiment can be achieved.

As described above, according to the first embodiment and its modification examples, it is possible to realize a semiconductor device with a high breakdown voltage. In addition, according to the first embodiment and its modification examples, it is possible to realize a semiconductor device manufacturing method capable of easily forming a deep p-type region.

### Second Embodiment

A semiconductor device according to a second embodiment is different from the semiconductor device according to the first embodiment in that a silicon carbide layer further includes a trench disposed on the first face side and extending in the second direction on the first face and a gate electrode is provided in the trench. In addition, a semiconductor device manufacturing method according to the second embodiment is different from the semiconductor device manufacturing method according to the first embodiment in that a trench is formed in the silicon carbide layer by using a mask material as a mask before the first processing and the first ion implantation. Hereinafter, the description of a part of the content overlapping the first embodiment may be omitted.

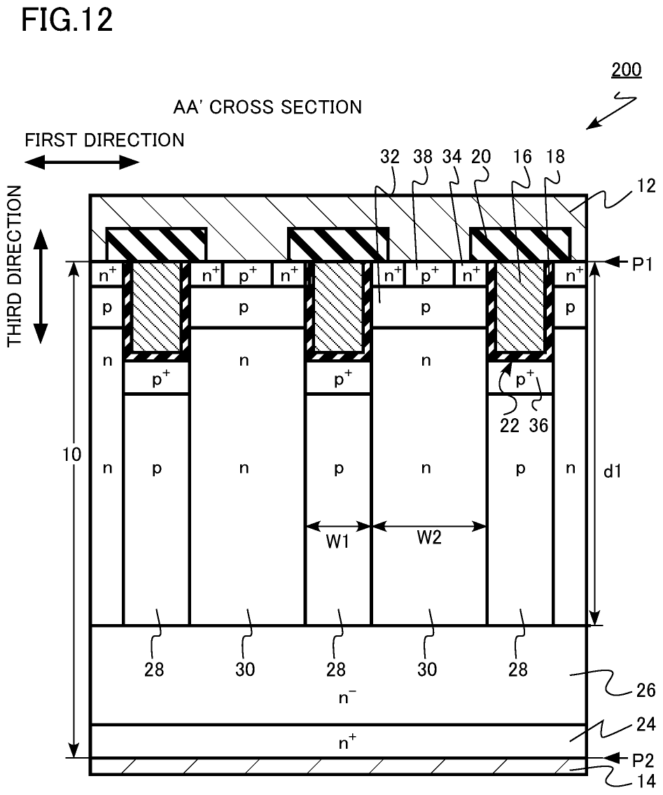

FIG. 12 is a schematic cross-sectional view of the semiconductor device according to the second embodiment. The semiconductor device according to the second embodiment is a trench gate type vertical MOSFET 200 using silicon carbide. The MOSFET 200 is an n-channel MOSFET having electrons as carriers. The MOSFET 200 has a superjunction structure (SJ structure).

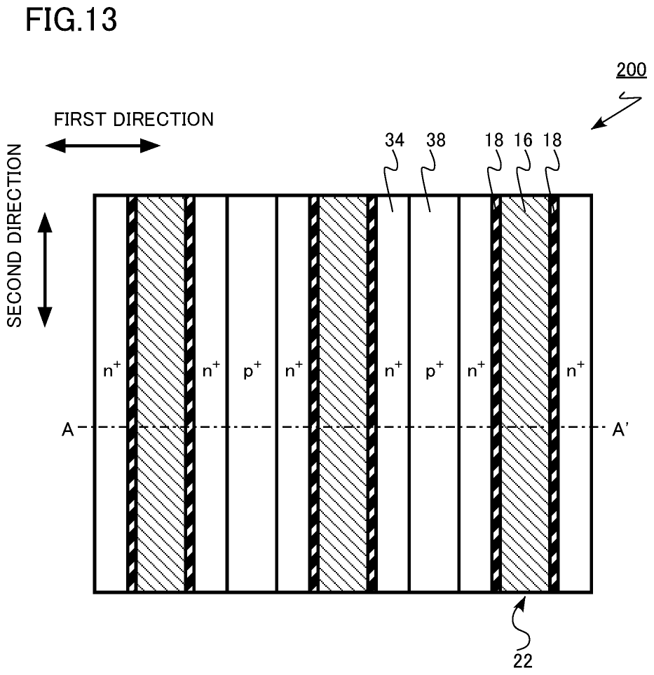

FIG. 13 is a schematic plan view of the semiconductor device according to the second embodiment. FIG. 13 is a plan view of a first face (P1 in FIG. 12) in FIG. 12. FIG. 12 is a cross-sectional view taken along the line AA′ of FIG. 13.

The MOSFET 200 includes a silicon carbide layer 10, a source electrode 12 (first electrode), a drain electrode 14 (second electrode), a gate electrode 16, a gate insulating layer 18, and an interlayer insulating layer 20.

The silicon carbide layer 10 includes a gate trench 22 (trench), an n⁺-type drain region 24, an n⁻-type drift region 26, a p-type p-pillar region 28 (first silicon carbide region), an n-type n-pillar region 30 (second silicon carbide region), a p-type body region 32 (third silicon carbide region), an n⁺-type source region 34 (fourth silicon carbide region), a p⁺-type electric field relaxation region 36, and a p⁺-type contact region 38.

The gate trench 22 is present in the silicon carbide layer 10. The gate trench 22 is disposed on the first face P1 side of the silicon carbide layer 10. The gate trench 22 is a groove formed in the silicon carbide layer 10.

The gate trench 22 extends in the second direction as shown in FIG. 13. The gate trench 22 is repeatedly arranged in the first direction as shown in FIG. 13. The pitch between the gate trenches 22 in the first direction is, for example, equal to or more than 1 μm and equal to or less than 5 μm. The depth of the gate trench 22 is, for example, equal to or more than 1 μm and equal to or less than 2 μm. The width of the gate trench 22 in the first direction is, for example, equal to or more than 0.5 μm and equal to or less than 1 μm.

The gate electrode 16 is disposed in the gate trench 22. The gate electrode 16 is provided between the source electrode 12 and the drain electrode 14. The gate electrode 16 extends in the second direction.

The gate insulating layer 18 is disposed between the gate electrode 16 and the silicon carbide layer 10. The gate insulating layer 18 is provided between the source region 34, the body region 32, the electric field relaxation region 36, and the n-pillar region 30 and the gate electrode 16.

The p-type p-pillar region 28 and the n-type n-pillar region 30 are provided between the drain region 24 and the first face P1. The p-pillar region 28 and the n-pillar region 30 are provided between the drift region 26 and the first face P1.

The p-pillar region 28 is provided between the gate trench 22 and the second face P2. The p-pillar region 28 is provided between the gate trench 22 and the drift region 26.

The p-pillar region 28 and the n-pillar region 30 are arranged alternately in the first direction. The p-pillar region 28 and the n-pillar region 30 form a so-called superjunction structure (SJ structure).

The p-pillar region 28 contains, for example, aluminum (Al) as a p-type impurity. The p-type impurity concentration in the p-pillar region 28 is, for example, equal to or more than 5×10¹⁵ cm⁻³ and equal to or less than 5×10¹⁷ cm⁻³.

The n-pillar region 30 contains, for example, nitrogen (N) as an n-type impurity. The n-type impurity concentration in the n-pillar region 30 is, for example, equal to or more than 5×10¹⁵ cm⁻³ and equal to or less than 5×10¹⁷ cm⁻³.

For example, assuming that the width of the p-pillar region 28 in the second direction is W1, the p-type impurity concentration in the p-pillar region 28 is N1, the width of the n-pillar region 30 in the second direction is W2, and the n-type impurity concentration in the n-pillar region 30 is N2, the following relationship is satisfied.

0.8≤(W1×N1)/(W2×N2)≤1.2 The aspect ratio (d1/W1) between the depth d1 of the p-pillar region 28 in the third direction and the width (W1 in FIG. 12) of the p-pillar region 28 in the second direction is, for example, equal to or more than 3. The depth d1 of the p-pillar region 28 in the third direction perpendicular to the first face is, for example, equal to or more than 5 μm and equal to or less than 10 μm.

The Z_{1/2} level density in the p-pillar region 28 measured by deep level transient spectroscopy (DLTS) is lower than the Z_{1/2} level density in the n-pillar region 30 measured by DLTS. The Z_{1/2} level density in the p-pillar region 28 is, for example, equal to or less than 50% of the Z_{1/2} level density in the n-pillar region 30.

The Z_{1/2} level density measured by DLTS corresponds to the density of carbon vacancies. The density of carbon vacancies in the p-pillar region 28 is lower than the density of carbon vacancies in the n-pillar region 30.

The p⁺-type electric field relaxation region 36 is disposed between the p-pillar region 28 and the gate trench 22. The electric field relaxation region 36 is in contact with the bottom surface of the gate trench 22. The electric field relaxation region 36 is in contact with the gate insulating layer 18. The electric field relaxation region 36 is in contact with the p-pillar region 28.

The electric field relaxation region 36 has a function of reducing the electric field applied to the gate insulating layer 18 when the MOSFET 200 is turned off. The electric field relaxation region 36 is fixed to, for example, the same electric potential as the electric potential of the source electrode 12.

The electric field relaxation region 36 contains, for example, aluminum (Al) as a p-type impurity. The p-type impurity concentration in the electric field relaxation region 36 is higher than the p-type impurity concentration in the p-pillar region 28. The p-type impurity concentration in the electric field relaxation region 36 is, for example, equal to or more than 10 times the p-type impurity concentration in the p-pillar region 28. The p-type impurity concentration in the electric field relaxation region 36 is, for example, equal to or more than 5×10¹⁷ cm⁻³ and equal to or less than 5×10¹⁹ cm⁻³.

Next, an example of a semiconductor device manufacturing method according to the second embodiment will be described.

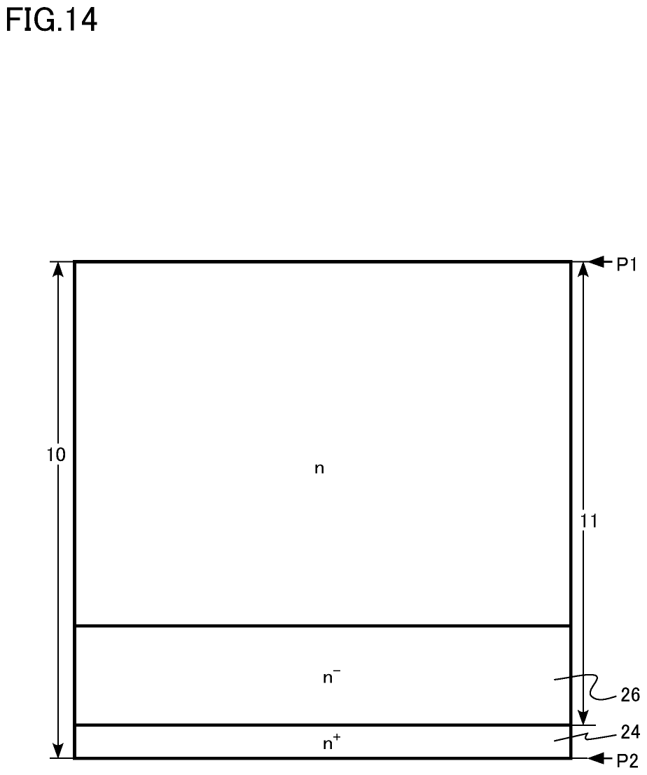

FIGS. 14 to 25 are schematic cross-sectional views showing an example of the semiconductor device manufacturing method according to the second embodiment. FIGS. 14 to 25 show cross sections corresponding to FIG. 12.

First, the silicon carbide layer 10 having an n⁺-type drain region 24 and an n⁻-type and n-type epitaxial layer 11 is prepared (FIG. 14). A part of the epitaxial layer 11 finally becomes the drift region 26 and the n-pillar region 30.

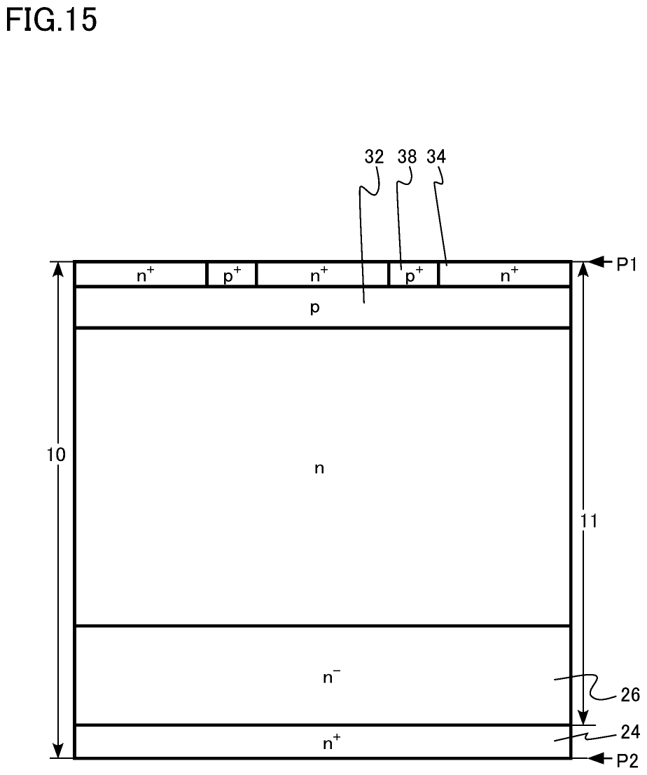

Then, the p-type body region 32, the n⁺-type source region 34, and the p⁺-type contact region 38 are formed in the epitaxial layer 11 by using known photolithography and ion implantation methods (FIG. 15).

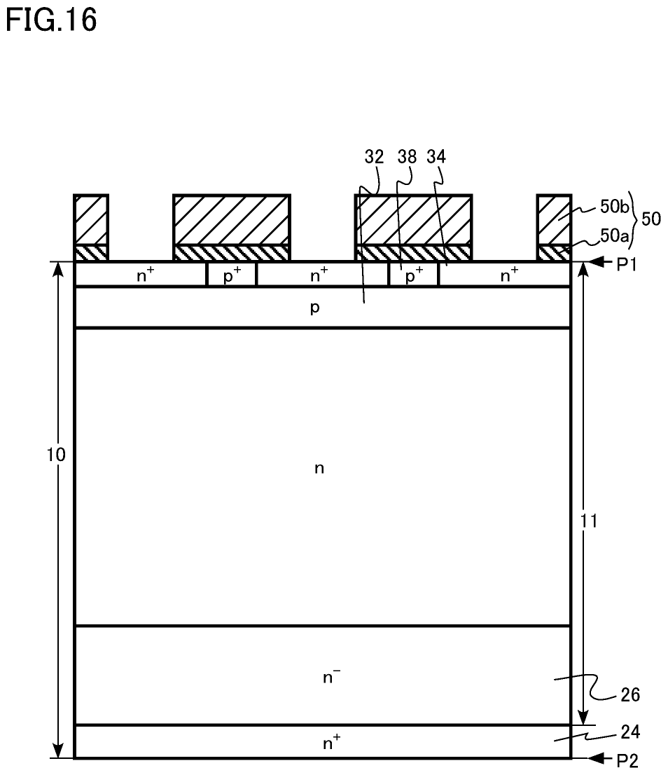

Then, a mask material 50 having openings is formed on the silicon carbide layer 10 (FIG. 16). The mask material 50 is, for example, a stacked film of a silicon oxide film 50a and a metal film 50b. The metal film 50b is, for example, tungsten.

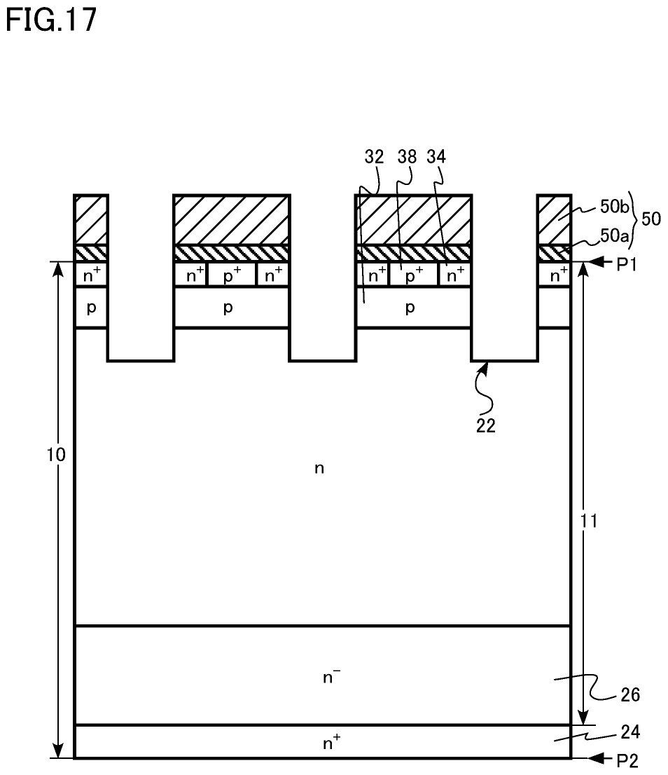

Then, using a known reactive ion etching method, the gate trench 22 is formed by using the mask material 50 as a mask (FIG. 17). The gate trench 22 is formed so as to penetrate the source region 34 and the body region 32.

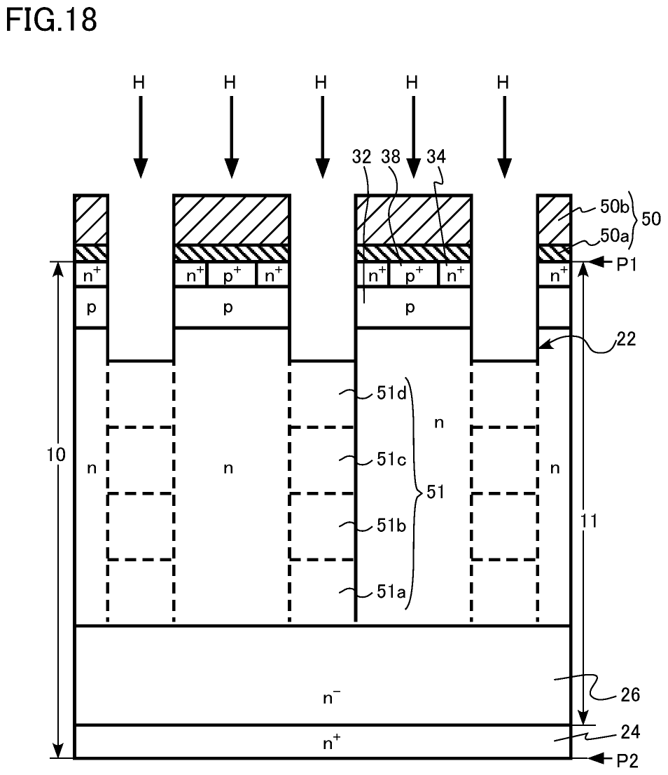

Then, using the mask material 50 as a mask, hydrogen (H) is ion-implanted into the silicon carbide layer 10 through the openings (FIG. 18). Hydrogen (H) is ion-implanted into the silicon carbide layer 10 from the bottom of the gate trench 22. Hydrogen (H) is an example of a substance. Ion implantation of hydrogen (H) is an example of the first processing.

By ion implantation of hydrogen (H), hydrogen (H) is implanted into the first region 51. Ion implantation of hydrogen (H) includes multiple ion implantations. For example, ion implantation of hydrogen (H) includes four ion implantations.

Four ion implantations are performed at different accelerating voltages. Through the four ion implantations, hydrogen (H) is implanted into a first portion 51a, a second portion 51b, a third portion 51c, and a fourth portion 51d at different depths.

Ion implantation of hydrogen (H) is performed so that the concentration of hydrogen (H) in the first region 51 is, for example, equal to or more than 1×10¹⁵ cm⁻³ and equal to or less than 1×10²¹ cm⁻³.

By the ion implantation of hydrogen (H), carbon vacancies are formed in the first region 51. Through the four ion implantations, carbon vacancies are formed in the first portion 51a, the second portion 51b, the third portion 51c, and the fourth portion 51d at different depths.

Ion implantation of hydrogen (H) is performed at a temperature equal to or more than 300° C., for example. Ion implantation of hydrogen (H) is performed, for example, while a holder on which the silicon carbide layer 10 is placed is held at a temperature equal to or more than 300° C. By performing the ion implantation of hydrogen (H) at a temperature equal to or more than 300° C., for example, a degradation in crystallinity of the silicon carbide layer 10 is suppressed.

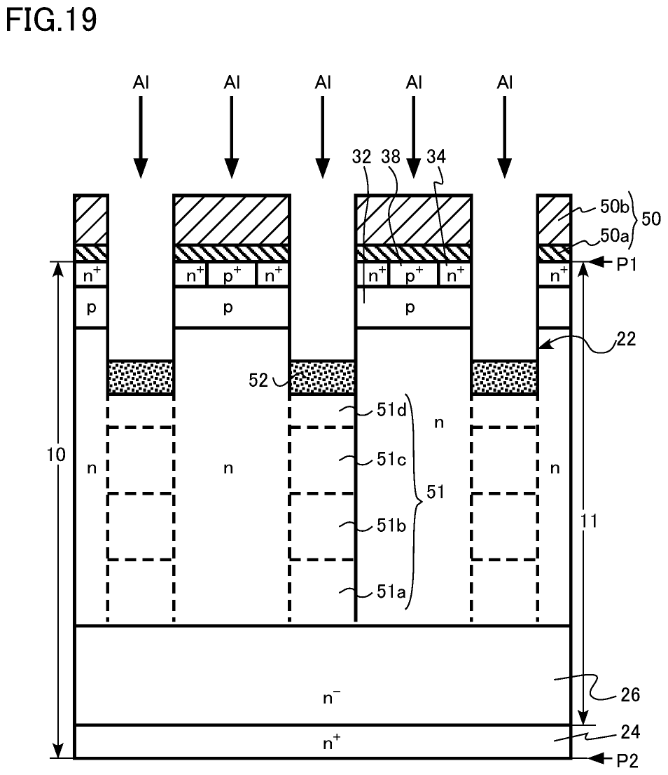

Then, aluminum (Al) is ion-implanted into the silicon carbide layer 10 by using the mask material 50 as a mask (FIG. 19). Ion implantation of aluminum (Al) is an example of the first ion implantation.

By the ion implantation of aluminum (Al), aluminum (Al) is implanted into a second region 52. The second region 52 is shallower than the first region 51. The second region 52 overlaps a part of the first region 51. The second region 52 overlaps a part of the fourth portion 51d, for example. The depth of the first region 51 is, for example, equal to or more than three times the depth of the second region 52.

Ion implantation of aluminum (Al) is performed at a temperature equal to or more than 300° C., for example.

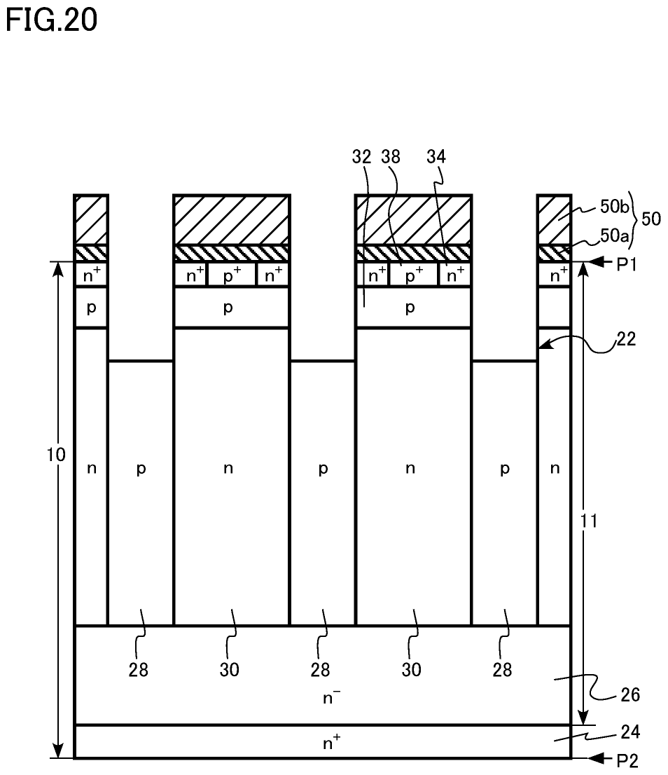

Then, a second heat treatment is performed at a temperature equal to or more than 300° C. (FIG. 20). The second heat treatment is performed in a non-oxidizing atmosphere. The second heat treatment is performed, for example, in an inert gas atmosphere. The second heat treatment is performed, for example, in an argon gas atmosphere.

Aluminum (Al) is diffused into the first region 51 by the second heat treatment, forming the p-pillar region 28. The region between the p-pillar region 28 and the p-pillar region 28 becomes the n-pillar region 30.

In addition, when ion implantation of aluminum (Al) is performed at a temperature equal to or more than 300° C., aluminum (Al) is diffused into the first region 51 even during the ion implantation of aluminum (Al). For example, if aluminum (Al) can be sufficiently diffused into the first region 51 during the ion implantation of aluminum (Al), the second heat treatment can be omitted.

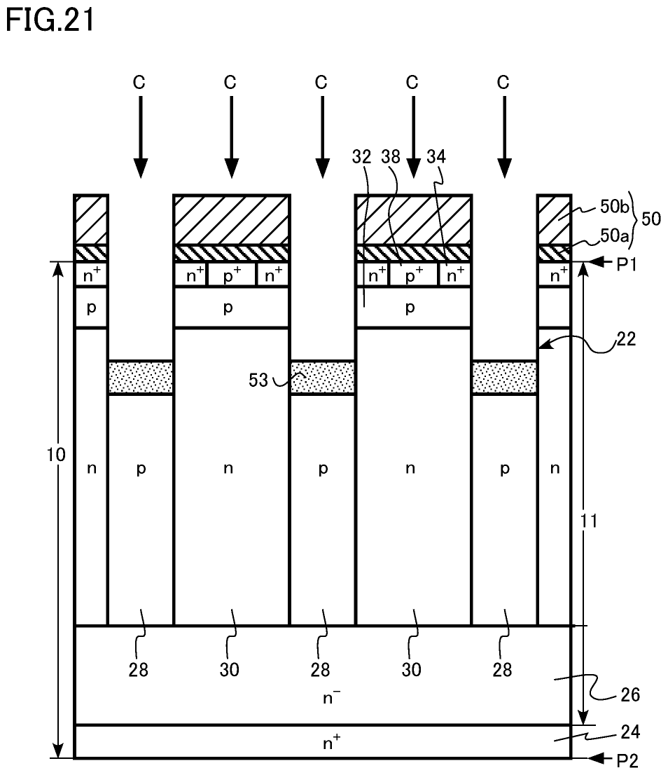

Then, a second ion implantation, which is ion implantation of carbon (C) into the silicon carbide layer 10, is performed by using the mask material 50 as a mask (FIG. 21). By the ion implantation of carbon (C), carbon (C) is implanted into a third region 53. The third region 53 is shallower than the first region 51.

Ion implantation of carbon (C) is performed at a temperature equal to or more than 300° C., for example.

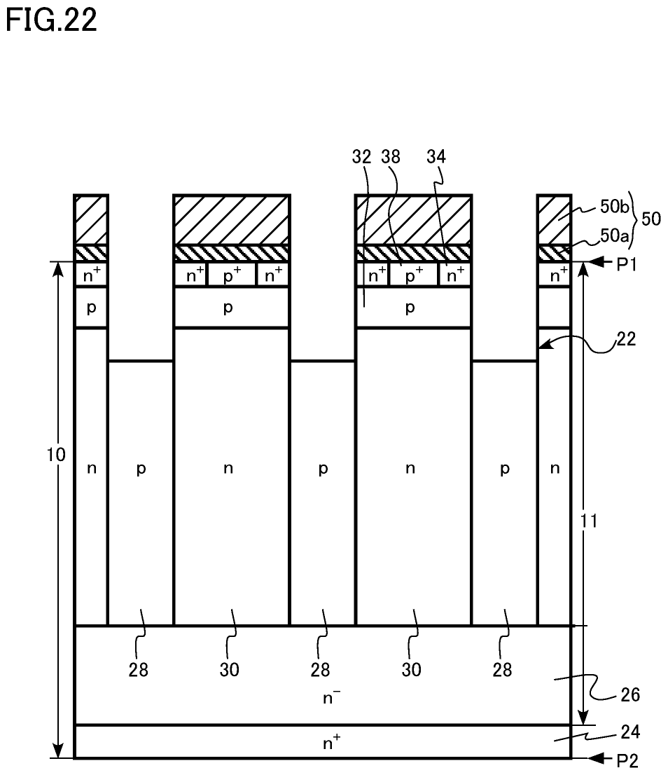

Then, a third heat treatment is performed at a temperature equal to or more than 300° C. (FIG. 22). The third heat treatment is performed in a non-oxidizing atmosphere. The third heat treatment is performed, for example, in an inert gas atmosphere. The third heat treatment is performed, for example, in an argon gas atmosphere.

By the third heat treatment, carbon (C) is diffused into the p-pillar region 28.

In addition, when ion implantation of carbon (C) is performed at a temperature equal to or more than 300° C., carbon (C) is diffused into the p-pillar region 28 during the ion implantation of carbon (C). For example, if carbon (C) can be sufficiently diffused into the p-pillar region 28 during the ion implantation of carbon (C), the third heat treatment can be omitted.

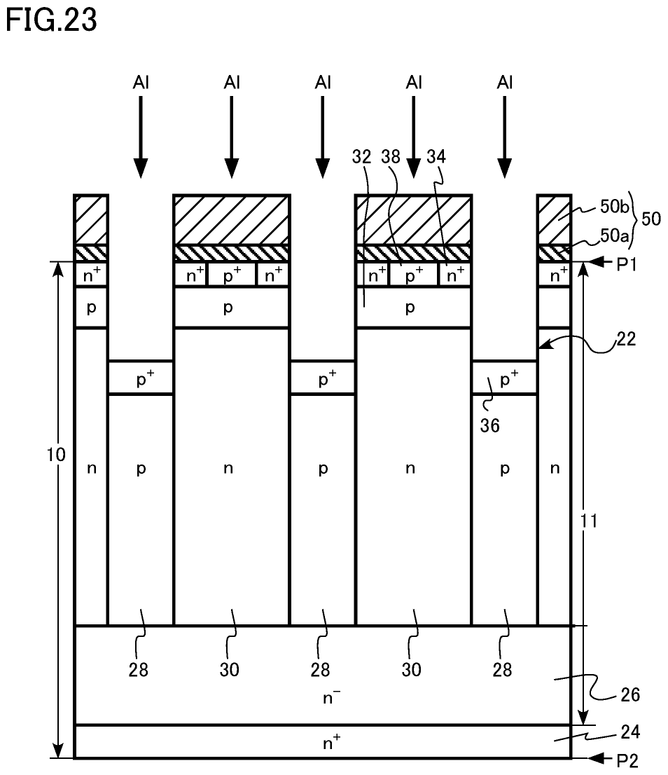

Then, aluminum (Al) is ion-implanted into the silicon carbide layer 10 by using the mask material 50 as a mask (FIG. 23). By the ion implantation of aluminum (Al), the p⁺-type electric field relaxation region 36 is formed at the bottom of the gate trench 22.

Then, the mask material 50 is removed. The mask material 50 is removed by using, for example, a wet etching method.

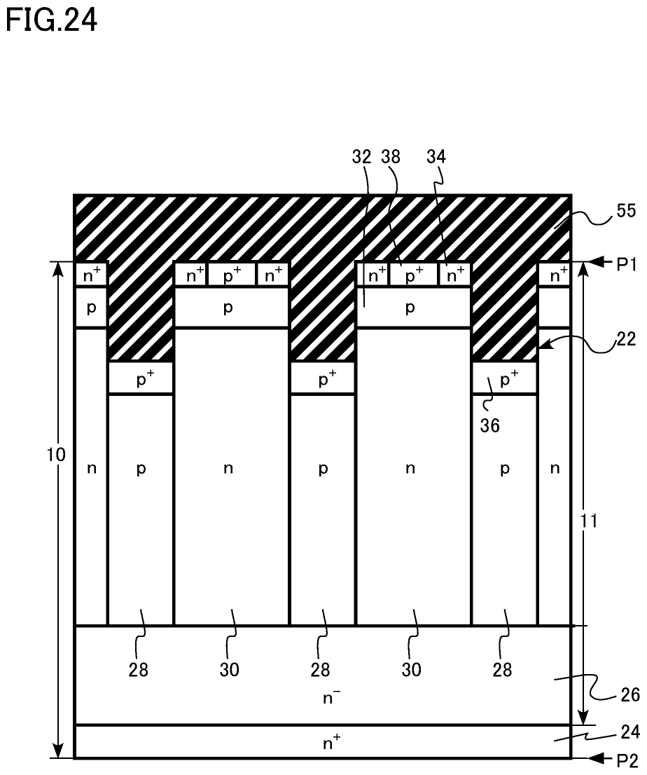

Then, the carbon film 55 is formed on the surface of silicon carbide layer 10 (FIG. 24).

Then, a first heat treatment is performed. The first heat treatment is performed at a temperature equal to or more than 1600° C. and equal to or less than 2000° C., for example. The first heat treatment is performed in a non-oxidizing atmosphere. The first heat treatment is performed, for example, in an inert gas atmosphere. The first heat treatment is performed, for example, in an argon gas atmosphere.

By the first heat treatment, ion-implanted aluminum (Al) is activated. In addition, through the first heat treatment, ion-implanted carbon (C) fills the carbon vacancies formed by ion implantation of hydrogen (H).

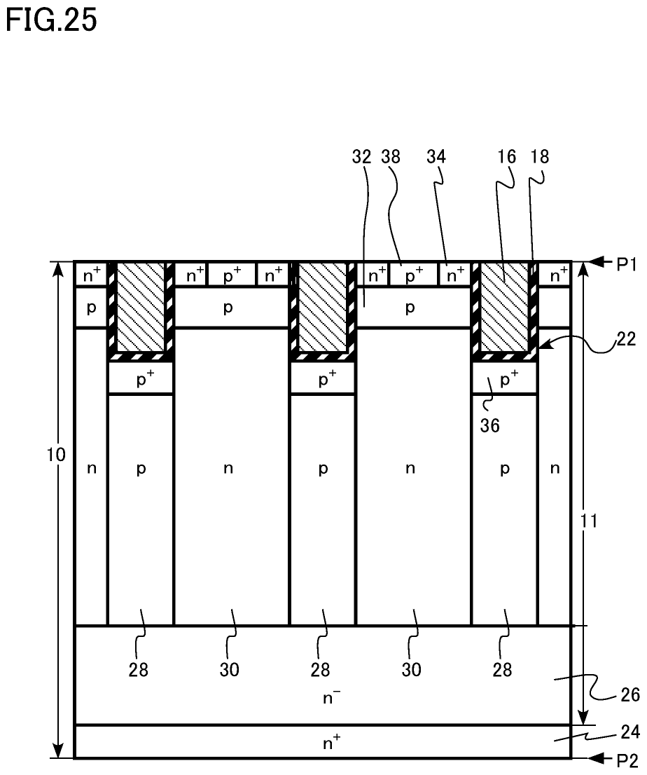

Then, the gate insulating layer 18 and the gate electrode 16 are formed in the gate trench 22 by using a known process technique (FIG. 25).

Then, the interlayer insulating layer 20, the source electrode 12, and the drain electrode 14 are formed by using a known process technique. By the manufacturing method described above, the MOSFET 200 shown in FIG. 12 is manufactured.

Since the MOSFET 200 has a trench gate structure, it is possible to reduce the on-resistance per unit area compared with the MOSFET 100 having a planar gate structure, for example.

In addition, the MOSFET 200 has an SJ structure formed by the p-pillar region 28 and the n-pillar region 30. Therefore, according to the MOSFET 200, it is possible to realize a high breakdown voltage and low on-resistance.

In the MOSFET 200, the Z_{1/2} level density in the p-pillar region 28 measured by deep level transient spectroscopy (DLTS) is lower than the Z_{1/2} level density in the n-pillar region 30 measured by DLTS. Therefore, in the MOSFET 200, the density of carbon vacancies in the p-pillar region 28 is lower than the density of carbon vacancies in the n-pillar region 30. Therefore, the balance between temporal changes in the depletion layer width of the p-pillar region 28 and the depletion layer width of the n-pillar region 30 is maintained. As a result, a high breakdown voltage of the MOSFET 200 can be realized.

According to the semiconductor device manufacturing method according to the second embodiment, a deep p-type region can be formed in a silicon carbide layer by using a simple manufacturing method with a small number of steps, similarly to the semiconductor device manufacturing method according to the first embodiment.

In addition, in the semiconductor device manufacturing method according to the second embodiment, for example, ion implantation of hydrogen (H) and multiple ion implantations of p-type impurities are performed by using the same mask material. Therefore, since there is no need to adjust the ion implantation, scaling-down of the MOSFET can be realized.

In addition, since the semiconductor device manufacturing method according to the second embodiment does not rely on channeling ion implantation, it is possible to form a p-type region with the same depth regardless of the crystal orientation of the surface of the silicon carbide layer 10. Therefore, according to the semiconductor device manufacturing method according to the second embodiment, it is possible to suppress variations in the depth of the p-type region.

As described above, according to the second embodiment, it is possible to realize a semiconductor device with a high breakdown voltage. In addition, according to the second embodiment, it is possible to realize a semiconductor device manufacturing method capable of easily forming a deep p-type region.

### Third Embodiment

A semiconductor device manufacturing method according to a third embodiment is different from the semiconductor device manufacturing methods according to the first and second embodiments in that a p⁺-type deep contact region is formed without forming an SJ structure. Hereinafter, the description of a part of the content overlapping the first or second embodiment may be omitted.

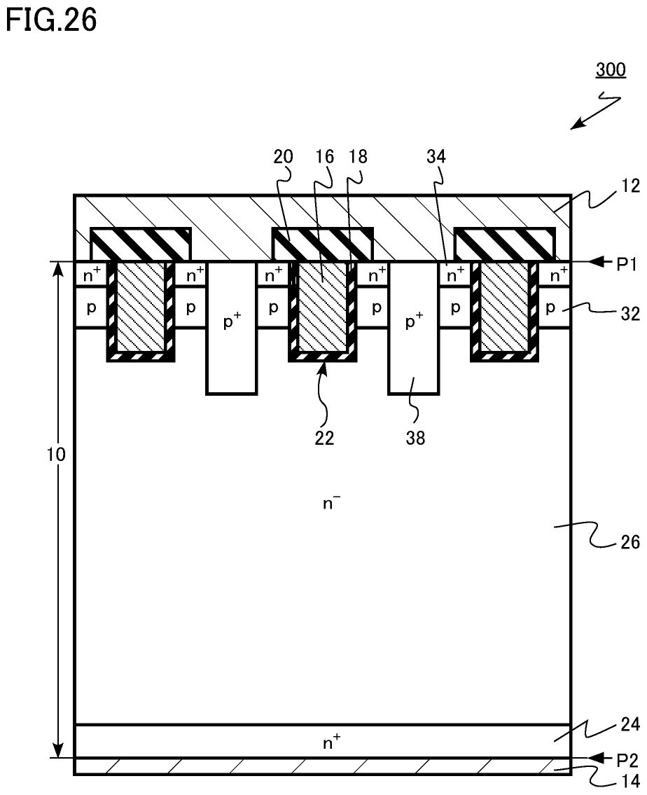

FIG. 26 is a schematic cross-sectional view of a semiconductor device manufactured by the semiconductor device manufacturing method according to the third embodiment. The semiconductor device according to the third embodiment is a trench gate type vertical MOSFET 300 using silicon carbide. The MOSFET 300 is an n-channel MOSFET having electrons as carriers.

The MOSFET 300 includes a silicon carbide layer 10, a source electrode 12, a drain electrode 14, a gate electrode 16, a gate insulating layer 18, and an interlayer insulating layer 20.

The silicon carbide layer 10 has a gate trench 22, an n⁺-type drain region 24, an n⁻-type drift region 26, a p-type body region 32, an n⁺-type source region 34, and a p⁺-type contact region 38.

The p⁺-type contact region 38 is disposed between the drift region 26 and the first face P1. The contact region 38 is in contact with the source electrode 12. The contact region 38 is provided between the two gate trenches 22. The depth of the contact region 38 is larger than the depth of the body region 32.

The contact region 38 contains, for example, aluminum (Al) as a p-type impurity. The p-type impurity concentration in the contact region 38 is higher than the p-type impurity concentration in the body region 32, for example. The p-type impurity concentration in the contact region 38 is, for example, equal to or more than 1×10¹⁸ cm⁻³ and equal to or less than 1×10²¹ cm⁻³.

Since the MOSFET 300 includes the deep contact region 38, the field strength applied to the gate insulating layer 18 when the MOSFET 300 is turned off is reduced. Providing the deep contact region 38 suppresses dielectric breakdown of the gate insulating layer 18 of the MOSFET 300, so that the reliability of the MOSFET 300 is improved.

Next, an example of the semiconductor device manufacturing method according to the third embodiment will be described.

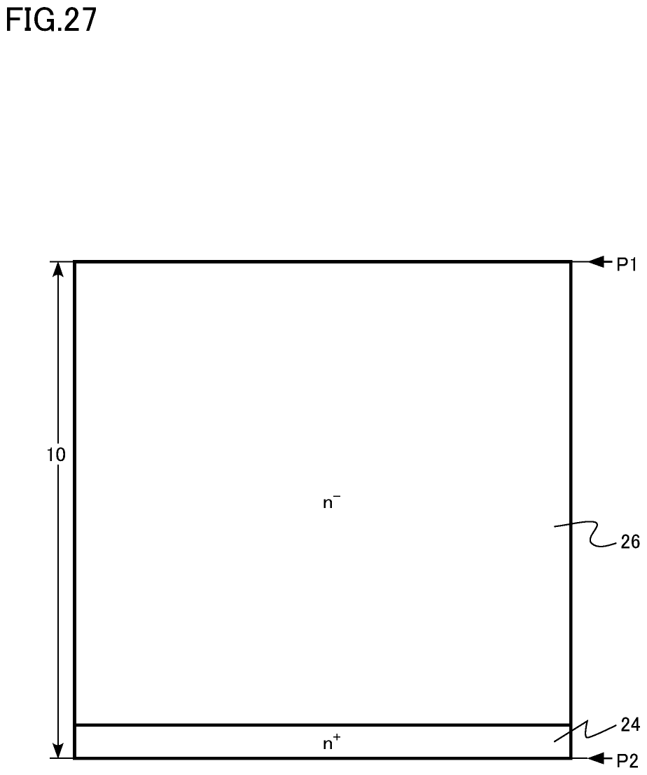

FIGS. 27 to 35 are schematic cross-sectional views showing an example of the semiconductor device manufacturing method according to the third embodiment. FIGS. 27 to 35 show cross sections corresponding to FIG. 26.

First, the silicon carbide layer 10 having an n⁺-type drain region 24 and an n⁻-type drift region 26 is prepared (FIG. 27). The drift region 26 is, for example, an epitaxial growth layer formed on the drain region 24.

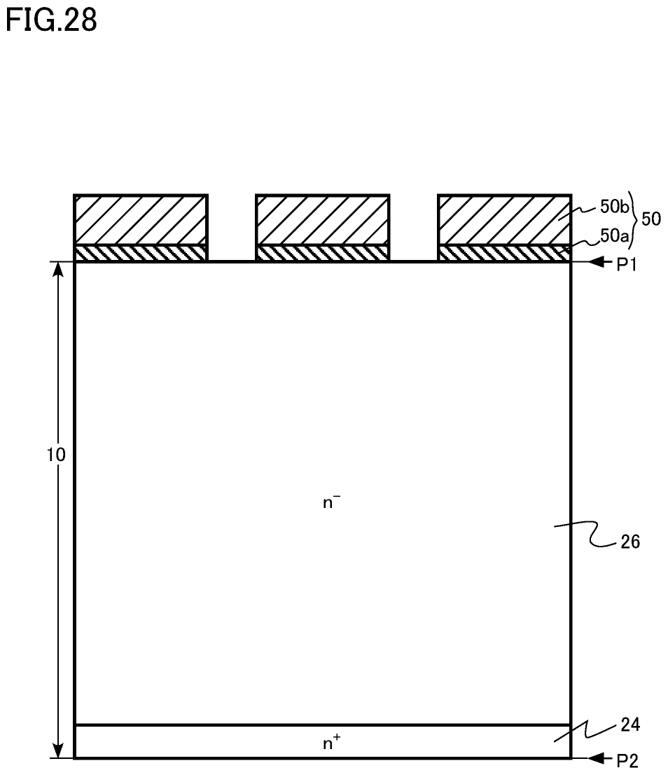

Then, a mask material 50 having openings is formed on the silicon carbide layer 10 (FIG. 28). The mask material 50 is, for example, a stacked film of a silicon oxide film 50a and a metal film 50b. The metal film 50b is, for example, tungsten.

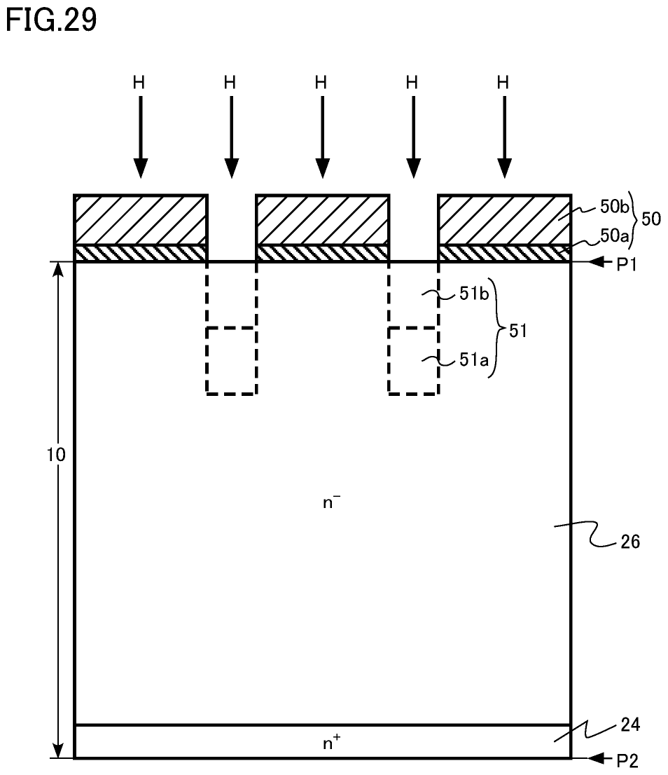

Then, hydrogen (H) is ion-implanted into the silicon carbide layer 10 by using the mask material 50 as a mask (FIG. 29). Hydrogen (H) is an example of a substance. Ion implantation of hydrogen (H) is an example of the first processing.

By ion implantation of hydrogen (H), hydrogen (H) is implanted into a first region 51. Ion implantation of hydrogen (H) includes multiple ion implantations. For example, ion implantation of hydrogen (H) includes two ion implantations.

Two ion implantations are performed at different accelerating voltages. Through the two ion implantations, hydrogen (H) is implanted into a first portion 51a and a second portion 51b at different depths.

Ion implantation of hydrogen (H) is performed so that the concentration of hydrogen (H) in the first region 51 is, for example, equal to or more than 1×10¹⁵ cm⁻³ and equal to or less than 1×10²¹ cm⁻³.

By the ion implantation of hydrogen (H), carbon vacancies are formed in the first region 51. Through the two ion implantations, carbon vacancies are formed in the first portion 51a and the second portion 51b at different depths.

Ion implantation of hydrogen (H) is performed at a temperature equal to or more than 300° C., for example. Ion implantation of hydrogen (H) is performed, for example, while a holder on which the silicon carbide layer 10 is placed is held at a temperature equal to or more than 300° C. By performing the ion implantation of hydrogen (H) at a temperature equal to or more than 300° C., for example, a degradation in crystallinity of the silicon carbide layer 10 is suppressed.

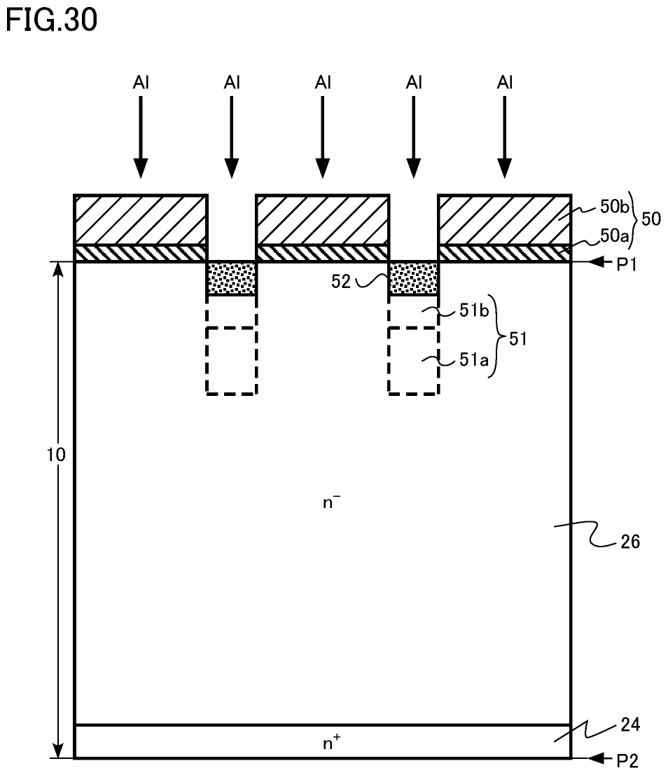

Then, aluminum (Al) is ion-implanted into the silicon carbide layer 10 by using the mask material 50 as a mask (FIG. 30). Ion implantation of aluminum (Al) is an example of the first ion implantation.

By the ion implantation of aluminum (Al), aluminum (Al) is implanted into a second region 52. The second region 52 is shallower than the first region 51. The second region 52 overlaps, for example, a part of the second portion 51b. The depth of the first region 51 is, for example, equal to or more than three times the depth of the second region 52.

Ion implantation of aluminum (Al) is performed at a temperature equal to or more than 300° C., for example.

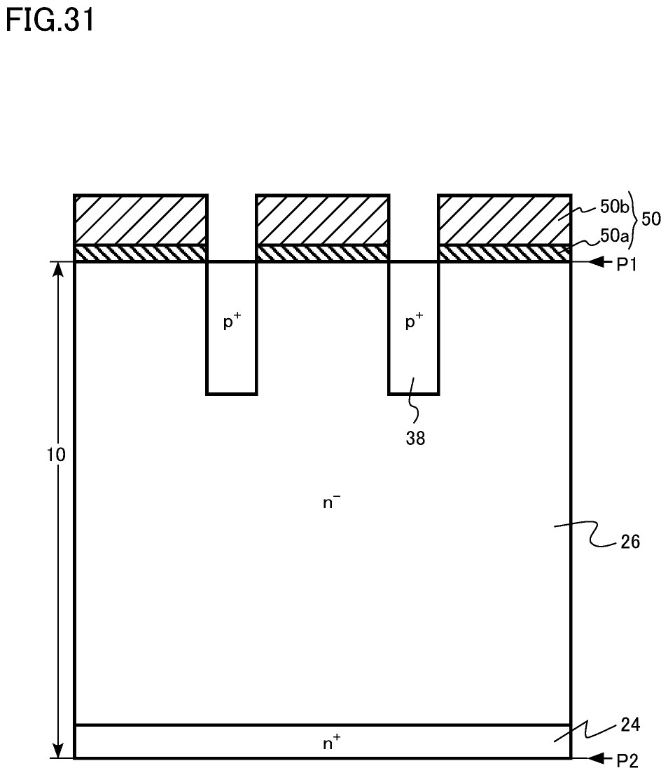

Then, a second heat treatment is performed at a temperature equal to or more than 300° C. (FIG. 31). The second heat treatment is performed in a non-oxidizing atmosphere. The second heat treatment is performed, for example, in an inert gas atmosphere. The second heat treatment is performed, for example, in an argon gas atmosphere.

Aluminum (Al) is diffused into the first region 51 by the second heat treatment, forming the p⁺-type contact region 38.

In addition, when ion implantation of aluminum (Al) is performed at a temperature equal to or more than 300° C., aluminum (Al) is diffused into the first region 51 even during the ion implantation of aluminum (Al). For example, if aluminum (Al) can be sufficiently diffused into the first region 51 during the ion implantation of aluminum (Al), the second heat treatment can be omitted.

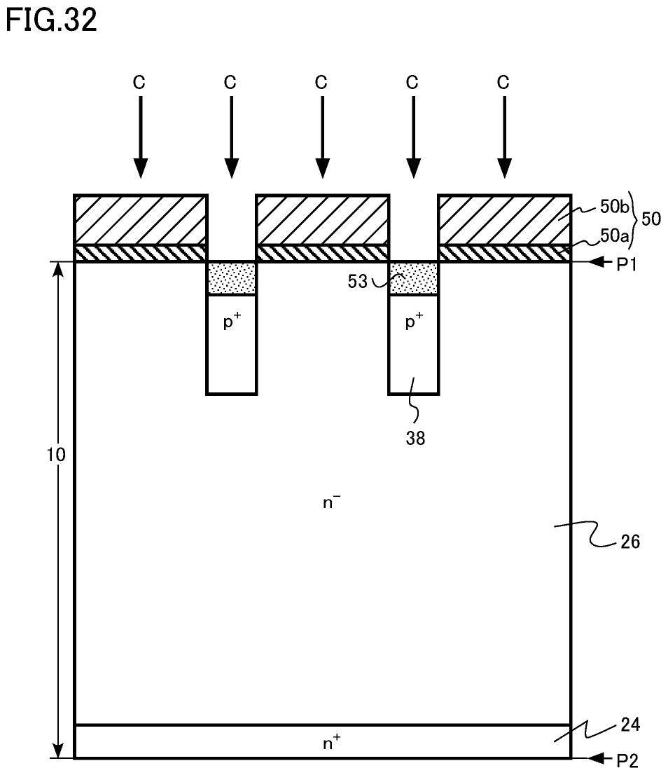

Then, a second ion implantation, which is ion implantation of carbon (C) into the silicon carbide layer 10, is performed by using the mask material 50 as a mask (FIG. 32). By the ion implantation of carbon (C), carbon (C) is implanted into a third region 53. The third region 53 is shallower than the first region 51.

Ion implantation of carbon (C) is performed at a temperature equal to or more than 300° C., for example.

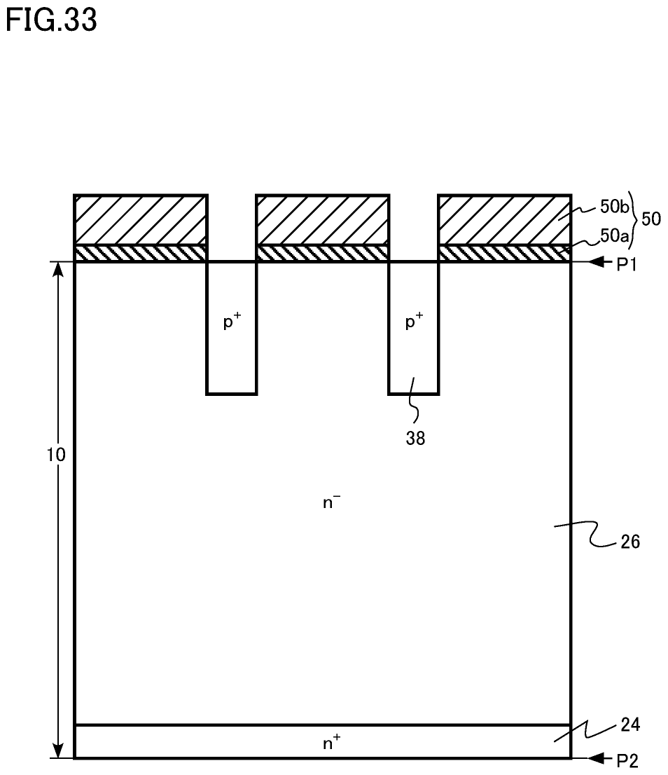

Then, a third heat treatment is performed at a temperature equal to or more than 300° C. (FIG. 33). The third heat treatment is performed in a non-oxidizing atmosphere. The third heat treatment is performed, for example, in an inert gas atmosphere. The third heat treatment is performed, for example, in an argon gas atmosphere.

By the third heat treatment, carbon (C) is diffused into the contact region 38.

In addition, when ion implantation of carbon (C) is performed at a temperature equal to or more than 300° C., carbon (C) is diffused into the contact region 38 during the ion implantation of carbon (C). For example, if carbon (C) can be sufficiently diffused into the contact region 38 during the ion implantation of carbon (C), the third heat treatment can be omitted.

Then, the mask material 50 is removed. The mask material 50 is removed by using, for example, a wet etching method.

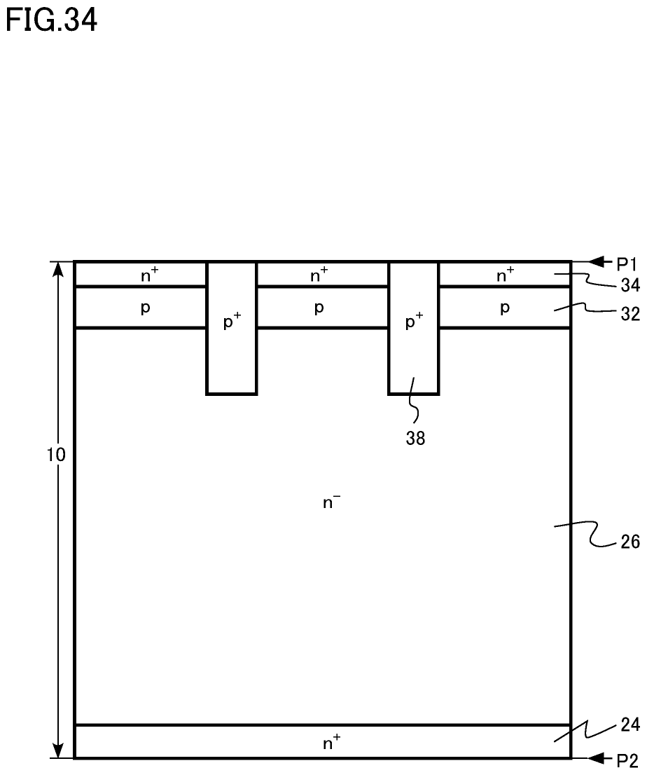

Then, the p-type body region 32 and the n⁺-type source region 34 are formed in the epitaxial layer 11 by using known photolithography and ion implantation methods (FIG. 34).

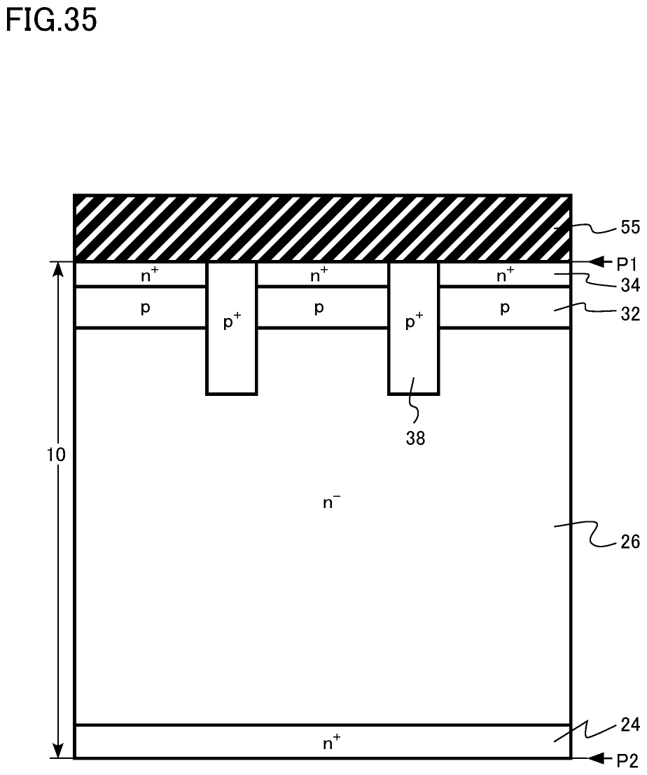

Then, a carbon film 55 is formed on the surface of the silicon carbide layer 10 (FIG. 35).

Then, a first heat treatment is performed. The first heat treatment is performed at a temperature equal to or more than 1600° C. and equal to or less than 2000° C., for example. The first heat treatment is performed in a non-oxidizing atmosphere. The first heat treatment is performed, for example, in an inert gas atmosphere. The first heat treatment is performed, for example, in an argon gas atmosphere.

By the first heat treatment, ion-implanted aluminum (Al) is activated. In addition, through the first heat treatment, ion-implanted carbon (C) fills the carbon vacancies formed by ion implantation of hydrogen (H).

Then, using a known process technique, the gate trench 22, the gate insulating layer 18, the gate electrode 16, the interlayer insulating layer 20, the source electrode 12, and the drain electrode 14 are formed. By the manufacturing method described above, the MOSFET 300 shown in FIG. 26 is manufactured.

According to the semiconductor device manufacturing method according to the third embodiment, a deep p-type region can be formed in a silicon carbide layer by using a simple manufacturing method with a small number of steps, similarly to the semiconductor device manufacturing method according to the first embodiment. In addition, for example, ion implantation of hydrogen (H) and multiple ion implantations of p-type impurities are performed by using the same mask material. Therefore, since there is no need to adjust the ion implantation, scaling-down of the MOSFET can be realized.

In addition, since the semiconductor device manufacturing method according to the third embodiment does not rely on channeling ion implantation, it is possible to form a p-type region with the same depth regardless of the crystal orientation of the surface of the silicon carbide layer 10. Therefore, according to the semiconductor device manufacturing method according to the third embodiment, it is possible to suppress variations in the depth of the p-type region.

In addition, according to the third embodiment, it is possible to realize a semiconductor device manufacturing method capable of easily forming a deep p-type region.

In addition, in the first to third embodiments, the n-type impurity is, for example, nitrogen or phosphorus. Arsenic (As) or antimony (Sb) can also be applied as an n-type impurity.

In addition, in the first to third embodiments, the p-type impurity is, for example, aluminum. Boron (B), gallium (Ga), and indium (In) can also be applied as p-type impurities.

In the first to third embodiments, the case of 4H-SiC has been described as an example of the crystal structure of silicon carbide. However, embodiments can also be applied to silicon carbide having other crystal structures, such as 6H-SiC and 3C-SiC.

In the first to third embodiments, the p-pillar region 28 or the contact region 38 has been described as an example of the deep p-type region. However, embodiments can also be applied to other deep p-type regions formed in the silicon carbide layer.

While certain embodiments have been described, these embodiments have been presented by way of example only, and are not intended to limit the scope of the inventions. Indeed, the semiconductor device manufacturing method and the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device manufacturing method, comprising:
forming a mask material having openings on a surface of a silicon carbide layer;
performing first processing for implanting at least one substance selected from a group consisting of hydrogen (H), helium (He), and electrons into a first region of the silicon carbide layer by using the mask material as a mask;
performing a first ion implantation for implanting p-type impurities into a second region shallower than the first region by using the mask material as a mask before the first processing or after the first processing;
removing the mask material after the first processing and the first ion implantation; and
performing a first heat treatment at a temperature equal to or more than 1600° C. after the removing the mask material.

2. The semiconductor device manufacturing method according to claim 1,
wherein the first processing includes a plurality of processes, and
in each of the plurality of processes, the at least one substance is implanted up to different depths of the silicon carbide layer.

3. The semiconductor device manufacturing method according to claim 1,
wherein the first ion implantation is performed after the first processing, and the first ion implantation is performed at a temperature equal to or more than 300° C.

4. The semiconductor device manufacturing method according to claim 1,
wherein a second heat treatment is performed at a temperature equal to or more than 300° C. before the removing the mask material after the first processing and the first ion implantation.

5. The semiconductor device manufacturing method according to claim 1,
wherein a second ion implantation for ion-implantation of carbon (C) is performed by using the mask material as a mask before the removing the mask material after the first ion implantation.

6. The semiconductor device manufacturing method according to claim 5,
wherein the second ion implantation is performed at a temperature equal to or more than 300° C.

7. The semiconductor device manufacturing method according to claim 5,
wherein a third heat treatment is performed at a temperature equal to or more than 300° C. before the removing the mask material after the second ion implantation.

8. The semiconductor device manufacturing method according to claim 1,
wherein a depth of the first region is equal to or more than three times a depth of the second region.

9. The semiconductor device manufacturing method according to claim 1,
wherein a depth of the first region is equal to or more than 5 μm.

10. The semiconductor device manufacturing method according to claim 1,
wherein the first processing is performed at a temperature equal to or more than 300° C.

11. The semiconductor device manufacturing method according to claim 1,
wherein a concentration of the at least one substance in the first region is equal to or more than 1×10¹⁵ cm⁻³ and equal to or less than 1×10²¹ cm⁻³.

12. The semiconductor device manufacturing method according to claim 1 further comprising:
forming a carbon film on the surface of the silicon carbide layer before the first heat treatment after the removing the mask material.

13. The semiconductor device manufacturing method according to claim 1,
wherein the mask material includes a metal film.

14. The semiconductor device manufacturing method according to claim 1 further comprising:
forming a trench in the silicon carbide layer by using the mask material as a mask before the first processing and the first ion implantation.

15. The semiconductor device manufacturing method according to claim 1,
wherein the p-type impurities are aluminum (Al) or boron (B).

16. A semiconductor device, comprising:
a first electrode;
a second electrode;
a silicon carbide layer disposed between the first electrode and the second electrode, having a first face parallel to a first direction and a second direction crossing the first direction and a second face parallel to the first direction and the second direction and opposite to the first face, and including a p-type first silicon carbide region and an n-type second silicon carbide region arranged alternately in the first direction, a p-type third silicon carbide region disposed between the second silicon carbide region and the first face, and an n-type fourth silicon carbide region disposed between the third silicon carbide region and the first face;
a gate electrode provided on a side of the first face of the silicon carbide layer, facing the third silicon carbide region, and extending in the second direction; and
a gate insulating layer disposed between the gate electrode and the silicon carbide layer,
wherein a Z_{1/2} level density in the first silicon carbide region measured by deep level transient spectroscopy (DLTS) is lower than a Z_{1/2} level density in the second silicon carbide region measured by DLTS.

17. The semiconductor device according to claim 16,
wherein the silicon carbide layer further includes a trench disposed on a side of the first face and extending in the second direction on the first face, and
the gate electrode is provided in the trench.

18. The semiconductor device according to claim 17,
wherein the first silicon carbide region is provided between the trench and the second face.
